(19) United States
(12) Patent Application Publication
(10) Pub. No.: US 2017/0338312 A1
(43) Pub. Date: Nov. 23, 2017

(54) DIRECT TRANSFER OF MULTIPLE GRAPHENE LAYERS ONTO MULTIPLE TARGET SUBSTRATES

(71) Applicant: SABIC Global Technologies B.V., Amsterdam (NL)

(72) Inventors: Emanuele Treossi, Bologna (IT); Alessandra Scidà, Bologna (IT); Vincenzo Palermo, Bologna (IT); Mohd Adnan Khan, Thuwal (SA)

(73) Assignee: SABIC Global Technologies B.V., Amsterdam (NL)

(21) Appl. No.: 15/522,528

(22) PCT Filed: Jul. 14, 2015
(86) PCT No.: PCT/IB2015/055329

§ 371 Date: Apr. 27, 2017

Related U.S. Application Data
(60) Provisional application No. 62/074,948, filed on Nov. 4, 2014.

(51) Int. Cl. H01L 29/16; B32B 7/12; B32B 9/00; B65H 20/02; B32B 37/12; B32B 3/26; H01L 21/02; C23F 1/16; H01L 21/683; B32B 15/04

(52) U.S. Cl. CPC H01L 29/1606; H01L 21/683; B32B 7/12; B32B 9/007; B32B 15/04; B32B 37/1207; B32B 3/266; H01L 21/02568; H01L 21/02527; C23F 1/16; B65H 20/02; B32B 2311/12; B32B 2311/22; B32B 2307/202; B65H 2301/44318; H01L 2221/68363

(57) ABSTRACT

Disclosed is a method of making a conductive material or active material that includes graphene or other 2-D materials. The method includes obtaining a layered stack. The layered stack including one or more conductive materials or 2-D materials separated by a metal layer, and one or more substrate materials. The stack can be subjected to a metal removal process to obtain two conductive or active materials. A first conductive or active material can include a first substrate layer attached to the first active layer. The second conductive or active material can include a second substrate layer attached to the second active layer. The first and second active layers can be conductive graphene layers.

### CROSS REFERENCE TO RELATED APPLICATIONS

This application claims benefit to U.S. Provisional Patent Application No. 62/074,948 titled “DIRECT TRANSFER OF MULTIPLE GRAPHENE LAYERS ONTO MULTIPLE TARGET SUBSTRATES”, filed Nov. 4, 2014. The contents of the referenced application are incorporated into the present application by reference.

### BACKGROUND OF THE INVENTION

A. Field of the Invention

The invention generally concerns a process for transferring graphene layers and other two dimensional materials from one substrate to another target substrate. The process can be used to simultaneously transfer graphene layers present on both sides of one substrate (e.g., metal substrate or layer) to two separate substrates, thereby increasing the efficiency of the graphene transfer process.

B. Description of Related Art

Graphene is pure carbon in the form of a one atom thick, planar sheet of sp2-bonded carbon atoms that are densely packed in a honeycomb crystal lattice. As a strictly 2D monolayer honeycomb of carbon atoms, graphene is the thinnest known material and the strongest ever measured. Graphene has many outstanding properties such as ultra-high electrical and thermal conductivity, optical transparency, impermeability to all molecular gases, high charge mobility, and ability to sustain extreme current densities. Graphene is also strong and flexible. Its charge carriers exhibit giant intrinsic mobility, have the smallest effective mass (it is zero), and can travel micrometer-long distances without scattering at room temperature. Graphene can sustain current densities six (6) orders higher than copper, demonstrate thermal conductivity and stiffness, is impermeable to gases, and reconciles such conflicting qualities as brittleness and ductility. Its outstanding properties suggest that graphene can replace other materials in existing applications. In particular, the combination of transparency, conductivity and elasticity will find use in flexible electronics, such as touch screen displays, electronic paper, and organic light-emitting diodes (OLEDs). Showing both excellent electrical and optical properties, graphene can be used as a replacement for indium tin oxide (ITO). Graphene also has outstanding mechanical flexibility and chemical durability, which are important characteristics for flexible electronic devices in which ITO usually fails. Current efforts have been directed to the improvement of the quality of a graphene material from large-scale production to reach the values achieved for single graphene sheet.

The market of graphene applications is currently driven by progress in the production and processing of graphene with properties appropriate for the specific application. The properties of a particular grade of graphene (and hence the pool of applications that can utilize it) strongly depends on the quality of the material, type of defects, substrate, and so forth, which are strongly affected by the processing method.

Chemical vaporization deposition (CVD) is a synthesis method where graphene film is grown on either side of a metal catalytic substrate (typically copper) in a furnace and heated under low vacuum to around 1000° C. The production of square meters of graphene has already been achieved by different labs. However, the complete CVD process is expensive due to the large energy consumption required for the removal of the copper support and transfer of graphene to a dielectric surface or other substrate of interest. The current transfer processes of graphene to a substrate requires many wet chemical processes; these can include deposition of polymers on CVD graphene, solvents, etchants, water rinses and final thermal annealing. Further, only one side or layer of the graphene is transferred, while the other side or layer of graphene on the metal catalytic substrate is typically discarded.

For example, poly(methyl methacrylate) (PMMA) (See, Li et al, Nano Letters, 2009, Vol. 2, pp. 4359-4363) or polydimethylsiloxane (PDMS) (See, Kim et al, Nature, 2009, Vol. 457, pp. 706-710) have been used as a support coating over the graphene permitting the etching and removal of the underlying metal substrate used for growth. PMMA is the most common polymer used for CVD graphene transfer as it gives good electrical results. In PMMA process, at the end of the metal etching, a “raft” of PMMA/graphene remains, which can be essentially “fished” out of the etching solution and placed onto a desired substrate, such as a silicon dioxide silicon (SiO₂/Si) wafer or polyethylene terephthalate (PET). The PMMA is then often dissolved away using a suitable solvent, such as acetone. The typical PMMA solvent removal process is incomplete, resulting in detectable residuals with X-Ray Photoelectron Spectroscopy (See, Pirkle et al, Appl. Phys. Lett. 2011, Vol. 99, pp. 122108-122108-3), which is reduced by subsequent vacuum annealing. The use of PMMA increases the process time and costs as the PMMA is not completely removed. Residual PMMA, can lead to defective and/or cracked graphene, and therefore, cause problems in creating devices containing graphene from PMMA processes. Thus, these types of processes suffer from the problems of presence of PMMA residues, high costs for the metal waste and poor scalability for industrial processes.

Other techniques have been developed for large area CVD graphene for large scale transfer of graphene to a substrate. Bae et al. in Nanotechnol. 2010, Vol. 5, pp. 574-478 uses a thermal release tape as a support for CVD graphene as a substitute for PMMA. In this case, the support is thermally removed, but it still can leave residues that make difficult the realization of devices. Kobayashi et al. in Appl. Phys let, 2013, Vol. 102 describes a process for large area graphene transfer is obtained with a UV photo-curable epoxy resin used to attach graphene to PET. Other processes, instead, try to recycle the grown substrate by removing the graphene using mechanical stripping (See, Yoon et al., Nano Lett., 2012, pp. 1448-1452) or by electrochemical peeling (See, Wang et al., Nano, 2012, Vol. 5 pp. 9927-9933). Han et al. in Nano, 2011, Vol. 6, pp. 56-65 describes a graphene transfer process using ethyl vinyl acetate (EVA) coated PET in a 50:50 ratio. The resulting sheets, however, were hazy and required annealing after the transfer process to make them acceptable for use.

Graphene has the potential to be used in transparent, flexible components in electronic devices. However, the current graphene transfer technologies suffer from being expensive and generally ineffective in producing industrial quantities of high quality graphene layers on target substrates.

### SUMMARY OF THE INVENTION

A solution to the problems associated with transferring graphene to flexible substrates has been discovered. The solution resides in the ability to increase the graphene transfer process (e.g., by at least 100% or double) by simultaneously utilizing both graphene layers present on a metal catalytic layer in the transfer process while also preserving the graphene layer's properties. Further, the process of the present invention can be performed with or without the use of supporting coatings (e.g., PMMA, PDMS, etc.), solvents, multiple water rinses, or a final thermal annealing step. In particular, two graphene laminates each having a conductive graphene layer and an underlying substrate (e.g., a dielectric or electrical insulator substrate) can be obtained from a single graphene stack (e.g., a CVD produced graphene stack can have a first graphene layer, a second graphene layer, and a catalytic metal layer positioned between the first and second graphene layers) by attaching a first substrate to the first graphene layer and a second substrate to the second graphene layer and then removing the catalytic metal layer. Attachment can be through an adhesive layer or through direct attachment via pressure, heat, plasma activation, electrostatic interaction, or any combination thereof. Removal of the catalytic metal layer releases each of the graphene layers, thereby producing the two separate graphene laminates. The produced graphene laminates can be used as electrodes or interconnects in flexible electronic devices. In some instances, two dimensional materials, patterned graphene or functionalized graphene is used in the present invention. Without wishing to be bound by theory, it is believed that this transfer process not only increases the production output by 100%, it also reduces the formation of air gaps between the graphene and substrate layers, thereby reducing the formation of cracks in the graphene layer upon flexing of the substrate and/or separation of the graphene layer from the substrate over time.

In one aspect of the present invention, there is disclosed a method of making a graphene laminate or a conductive or active material, the method comprising obtaining a layered stack comprising a first substrate layer, a graphene layer attached to the first substrate layer, a metal layer attached to the first graphene layer, a second graphene layer attached to the metal layer, and a second substrate layer attached to second graphene layer, removing the metal layer from the layered stack, and obtaining two graphene laminates or conductive or active materials, wherein the first graphene laminate or conductive or active material comprises the first substrate layer attached to the first graphene layer, wherein the second graphene laminate or conductive or active material comprises the second substrate layer attached to the second graphene layer, and wherein the first and second graphene layers are conductive layers or active layers. The attachment of the first substrate layer to the first graphene layer can be obtained through a first adhesive layer positioned between the first substrate layer and the first graphene layer. Similarly, attachment of the second substrate layer to the second graphene layer can also be obtained through a second adhesive layer positioned between the second substrate layer and the second graphene layer. The adhesive layers can each be a thermally activated adhesive, a pressure activated adhesive, a solvent activated adhesive, an UV activated adhesive, a plasma active adhesive, or any combination thereof. In particular embodiments, the first and second adhesive layers each comprise a thermally activated adhesive, non-limiting examples of which include polyethylene acrylate polymer or copolymer thereof, ethylene vinyl acetate copolymer (EVA), ethylene methyl acrylate copolymers (EMA), ethylene acrylic acrylate (EAA), ethylene ethyl acrylate (EEA), or ethylene methyl acidic acrylate (EMAA). Further, any combination of adhesives can be used. Alternatively, the first and second substrates can be directly attached to the first and second graphene layers, non-limiting examples of which can include the use of heat, pressure, heat and pressure, plasma activation, or electrostatic interaction. For instance, heating of the substrate layer followed by pressing the substrate layer to the graphene layer can allow the graphene layer to directly attach to the substrate layer. In certain instances, a portion of the graphene layer can be embedded into the surface of the substrate layer. With respect to electrostatic interaction, either or both of the graphene and substrate layers can have opposing charges imparted onto the surfaces of each layer, thereby allowing for direct attachment through electrostatic interaction between the surface of the graphene layer and the surface of the substrate layer. Plasma activation can be used on the substrate layer via plasma treatment such that the surface of the substrate layer is functionalized in a manner that increases the adhesion between treated substrate layer and the graphene layer. For example, the functional groups created on the surface of the substrate layer via plasma treatment can interact with the graphene layer. It is contemplated in the context of the present invention that the first substrate layer can be attached to the first graphene layer by any one of the aforementioned attachment processes. Similarly, the second substrate layer can be attached to the second graphene layer by any one of the aforementioned attachment processes. In preferred aspects, both the first and second graphene layers are attached to the first and second substrate layers via an adhesive, most preferably via a thermally activated adhesive. The layered stack can be obtained by subjecting a graphene stack to a lamination process that includes attaching the first substrate layer to the first graphene layer and attaching the second substrate layer to the second graphene layer. In a preferred embodiment, the graphene stack can be produced by chemical vapor deposition of graphene onto each opposing side of the metal layer. The graphene stack can include the first graphene layer, the metal layer, and the second graphene layer. A first adhesive layer can be directly attached to the first graphene layer and is opposite the metal layer. A second adhesive layer can be directly attached to the second graphene layer and is opposite the metal layer. Alternatively, a first adhesive layer can be directly attached to the first substrate layer and/or a second adhesive layer can be attached to the second substrate layer. In a preferred embodiment, the first substrate layer can be attached to the first graphene layer and the second substrate layer can be attached to the second graphene layer simultaneously. Alternatively, the attachments can be performed sequentially or not simultaneously. The attachments can be performed via a roll-to-roll process or via a press process (e.g., hot press). The metal layer in the layered stack or in the graphene stack can be a catalytic metal (e.g., a metal that allows for the growth or deposition of graphene such as copper, nickel, ruthenium, palladium, iridium, platinum, rhodium, silver, gold, germanium, or any combination thereof. The metal layer can be removed by a chemical process, a mechanical process, an electrochemical process or other known metal removal methods. In one embodiment, the metal layer removal is performed by a chemical etching technique by subjecting the layered stack to an etching solution (e.g., an iron chloride solution, ammonium persulfate solution, a nitric acid solution, or the like.). In an embodiment, a mechanical process can include mechanical delamination. In one embodiment, an electrochemical process can include applying direct current voltage to the graphene stack used as a cathode and a glassy carbon anode in an electrolytic cell with NaOH, (NH₄)₂S₂O₈, or K₂S₂O₈. The hydrogen generated during the electrochemical process can delaminate the metal from the graphene layer. The first and/or second substrates, the first and/or second adhesive layers, the first and/or second graphene layers, or combinations thereof, can each be perforated or partially perforated. In some instances, the graphene stack can be patterned or functionalized. In certain instances, each or both of the first and second substrate layers can be polymeric layers. Further, each or both of the substrate layers can be transparent, translucent, or opaque. Non-limiting examples of polymers that can be used to form the polymeric layers include polyethylene terephthalate (PET), a polycarbonate (PC) family of polymers, polybutylene terephthalate (PBT), poly(1,4-cyclohexylidene cyclohexane-1,4-dicarboxylate) (PCCD), glycol modified polycyclohexyl terephthalate (PCTG), Poly(phenylene oxide) (PPO), polypropylene (PP), polyethylene (PE), polyvinyl chloride (PVC), polystyrene (PS), polyethyleneimine, thermoplastic elastomer (TPE), terephthalic acid (TPA) elastomers, poly(cyclohexanedimethylene terephthalate) (PCT), polyethylene naphthalate (PEN), polyamide (PA), polystyrene sulfonate (PSS), polyether ether ketone (PEEK), or polyetherimide (PEI), or combinations or blends thereof. In a preferred embodiment, the first substrate layer and the second substrate layer each comprise PET. Alternatively, each of the first and/or second substrate layers can be a polymethylmethacrylate (PMMA) layer, polydimethylsiloxane (PDMS) layer, or a thermal release tape. In a preferred aspect, each of the substrate layers are dielectric layers and the graphene layers are each conductive layers (for example, the produced graphene laminates can each have a sheet resistance of 300 ohm (Ω) to 2 kΩ/sq).

Also disclosed is a graphene laminate made by the processes disclosed above and throughout the present specification. The graphene laminate can be a conductive material such as a graphene electrode.

In another embodiment of the present invention there is disclosed a layered stack comprising a first substrate layer, a first graphene layer attached to the first substrate layer, a metal layer attached to the first graphene layer, a second graphene layer attached to the metal layer, and a second substrate layer attached to second graphene layer. The first and second substrate layers can be those described above and throughout the present invention. Similarly, the first and second graphene layers can be those described above and throughout this specification. The attachment of each of these layers to one another can also be those described above and throughout this specification (e.g., use of adhesive layers, direct attachment via heat, pressure, heat and pressure, plasma activation, CVD deposition process of graphene layers to metal layer, etc.).

In still another embodiment of the present invention, there is disclosed a graphene stack. The graphene stack can include a first adhesive layer attached to a first graphene layer, a metal layer attached to the first graphene layer opposite the first adhesive layer, and a second graphene layer attached to the metal layer opposite the first graphene layer. A second adhesive layer can also be attached to the second graphene layer opposite the metal layer. In addition to allowing attachment to substrate layers, the first and/or second adhesive layers can also serve to protect the graphene layers prior to attachment (e.g., during shipping or storage). The adhesive can be those disclosed above and throughout the specification. In a preferred aspect, the adhesive can be a thermal activated adhesive or a combination of thermally active adhesives such as those disclosed above and throughout the specification. The protective layer in the form of a thermoplastic film can be attached to the first adhesive layer, the second graphene layer, the second adhesive layer, the second graphene layer, or combinations thereof.

In yet another aspect of the present invention, there is disclosed a method to make a graphene laminate or conductive or active material by directly transferring at least one graphene layer from a metal layer to a substrate layer. The method can include (a) obtaining a graphene stack comprising a metal layer and a graphene layer; (b) adhering a substrate layer to the graphene layer with an adhesive to form a layered stack comprising the metal layer, the graphene layer, an adhesive layer, and the substrate layer; and (c) removing the metal layer to obtain a graphene laminate comprising the substrate layer, the graphene layer and the adhesive layer positioned between the polymeric and graphene layer. The adhesive can be deposited on the substrate layer, the graphene layer, or both prior to step (b). In some aspects, a second graphene layer can be present on the metal layer opposite from the first graphene layer. A protective layer can be positioned between the second substrate layer and the second graphene layer. The protective layer can be paper or any non-reactive flexible material. In certain aspects of the invention, a roll-to-roll process can be used for steps (b) and (c).

While the present invention has used graphene in the description of the conductive material, it should be understood that this present invention applies to other conductive material or active material. By way of example only, one such active material that can be used in the transfer processes of the present invention includes patterned graphene, functionalized graphene, or other 2-dimensional active materials, other patterned 2-dimensional active materials, or other functionalized 2-dimensional active layers. For example, boron nitride (e.g., CVD produced boron nitride, where a metal layer includes on each opposing side first and second boron nitride layers). Other non-limiting examples include 2-D materials grown or deposited metals, for example, h-BN, MoS₂, NbSe₂, WS₂, NiS₂, MoSe₂, WSe₂, VSe₂, TiS₂. Other 2-D materials functionalized by chemical or physical treatments are also contemplated. For example, functionalization by covalent bonding (the addition of free radicals to sp² carbon atoms of graphene, or addition of dienophiles to carbon-carbon bonds, or addition of chromophores, or addition of other organic molecules, or linkage to polymers, or attachments of hydrogen and halogens toward graphene derivatives like graphene or fluorographene); the functionalization by non-covalent bonding of graphene; the functionalization with nanoparticles (precious metal nanoparticles, metal oxide nanoparticles, quantum dots, etc.) and doping processes. These 2-D materials are used in optoelectronics, catalysis, batteries, super capacitors, ultrasensitive sensors for pressure changes, gas storage or separation, lubricants, and the like. In one embodiment, a method of making an active material can include obtaining a layered stack that includes a first substrate layer, a first 2-dimensional active material layer attached to the first substrate layer, a metal layer attached to the first 2-dimensional layer, a second 2-dimensional layer attached to the metal layer; removing the metal layer and the second 2-dimensional material from the layered stack; and obtaining one active materials that comprises the first substrate layer attached to the first 2-dimensional layer. The first 2-dimensional layer can be an active layer that is optionally patterned or functionalized and includes graphene, h-BN, MoS₂, NbSe₂, WS₂, NiS₂, MoSe₂, WSe₂, VSe₂, TiS₂, or any combination thereof. In some embodiments, the first substrate layer and/or second substrate layer is perforated.

In the context of the present invention embodiments 1 through 81 are described. Embodiment 1 is a method of making a conductive material. The method includes (a) obtaining a layered stack that includes a first substrate layer, a graphene layer attached to the first substrate layer, a metal layer attached to the first graphene layer, a second graphene layer attached to the metal layer, and a second substrate layer attached to second graphene layer; (b) removing the metal layer from the layered stack; and (c) obtaining two conductive materials, wherein the first conductive material includes the first substrate layer attached to the first graphene layer, wherein the second conductive material includes the second substrate layer attached to the second graphene layer, and wherein the first and second graphene layers are conductive layers. Embodiment 2 is the method of embodiment 1, wherein the first and second substrate layers are polymeric layers. Embodiment 3 is the method of embodiment 2, wherein the first and second polymeric layers are each polyethylene terephthalate layers and the metal layer is a copper layer or a nickel layer. Embodiment 4 is the method of any one of embodiments 1 to 3, wherein the first substrate layer and the first graphene layer are attached together through a first adhesive layer positioned between the first substrate layer and the first graphene layer. Embodiment 5 is the method of embodiment 4, wherein the second substrate layer and the second graphene layer are attached together through a second adhesive layer positioned between the second substrate layer and the second graphene layer. Embodiment 6 is the method of any one of embodiments 4 to 5, wherein the first and second adhesive layers include a thermally activated adhesive, a pressure activated adhesive, a solvent activated adhesive, a UV activated adhesive, a plasma active adhesive, or any combination thereof. Embodiment 7 is the method of embodiment 6, wherein the first and second adhesive layers each comprise a thermally activated adhesive. Embodiment 8 is the method of embodiment 7, wherein the thermally activated adhesive is a polyethylene acrylate polymer or copolymer thereof, ethylene vinyl acetate copolymer (EVA), ethylene methyl acrylate copolymers (EMA), ethylene acrylic acrylate (EAA), ethylene ethyl acrylate (EEA), or ethylene methyl acidic acrylate (EMAA), or any combination thereof. Embodiment 9 is the method any one of embodiments 1 to 3, wherein the first substrate layer and the first graphene layer are attached together by heat, pressure, plasma activation, electrostatic interaction, or any combination thereof. Embodiment 10 is the method of embodiment 9, wherein the second substrate layer and the second graphene layer are attached together by heat, pressure, plasma activation, electrostatic interaction, or any combination thereof. Embodiment 11 is the method of embodiment 9, wherein the second substrate layer and the second graphene layer are attached together through a first adhesive layer positioned between the second substrate layer and the second graphene layer. Embodiment 12 is the method of any one of embodiments 1 to 11, wherein the layered stack is obtained by subjecting a graphene stack to a lamination process that includes attaching the first substrate layer to the first graphene layer and attaching the second substrate layer to the second graphene layer. Embodiment 13 is the method of embodiment 12, wherein the graphene stack is produced by chemical vapor deposition of graphene onto each opposing side of the metal layer. Embodiment 14 is the method of any one of embodiments 12 to 13, wherein the graphene stack comprises the first graphene layer, the metal layer, and the second graphene layer. Embodiment 15 is the method of embodiment 14, wherein a first adhesive layer is attached to the first graphene layer and is opposite the metal layer. Embodiment 16 is the method of embodiment 15, wherein a second adhesive layer is attached to the second graphene layer and is opposite the metal layer. Embodiment 17 is the method of any one of embodiments 12 to 14, wherein a first adhesive layer is attached to the first substrate layer. Embodiment 18 is the method of embodiment 17, wherein a second adhesive layer is attached to the second substrate layer. Embodiment 19 is the method of any one of embodiments 12 to 18, wherein adhering the first substrate layer to the first graphene layer and the second substrate layer to the second graphene layer are performed simultaneously. Embodiment 20 is the method of any one of embodiments 12 to 18, wherein adhering the first substrate layer to the first graphene layer and the second substrate layer to the second graphene layer are not performed simultaneously. Embodiment 21 is the method of any one of embodiments 12 to 20, wherein a roll-to-roll process is used to make the layered stack. Embodiment 22 is the method of any one of embodiments 12 to 20, wherein a press-process is used to make the layered stack. Embodiment 23 is the method of any one of embodiments 1 to 22, wherein a roll-to-roll process is used to make the first and second conductive materials. Embodiment 24 is the method of any one of embodiments 1 to 22, wherein a press process is used to make the first and second conductive materials. Embodiment 25 is the method of any one of embodiments 1 to 24, wherein the metal layer comprises a catalytic metal. Embodiments 26 is the method of embodiment 25, wherein the catalytic metal is copper (Cu), palladium (Pd), platinum (Pt), ruthenium (Ru), iridium (Jr), cobalt (Co), silver (Ag), gold (Au), germanium (Ge), and nickel (Ni). Embodiment 27 is the method of any one of embodiments 1 to 26, wherein the metal layer is removed by a chemical process, a mechanical process, or an electrochemical process. Embodiment 28 is the method of embodiment 27, wherein the metal layer is removed by a chemical process comprising etching with an aqueous solution comprising iron chloride, ammonium persulfate, or nitric acid. Embodiment 29 is the method of embodiment 27, wherein the metal layer is removed by a mechanical process comprising delamination. Embodiment 30 is the method of embodiment 27, wherein the metal layer is removed by an electrochemical process comprising application of direct current. Embodiment 31 is the method of embodiment 30, wherein the electrochemical process includes utilizing the layered stack as a cathode or anode in an electrolytic cell, wherein the gas formation and/or partial etching of the metal layer detaches the graphene layers from the metal layer. Embodiment 32 is the method of embodiment 31, wherein the electrolytic cell comprises a carbon anode in a in a solution comprising NaOH, or (NH₄)₂S₂O₈, or K₂S₂O₈. Embodiment 33 is the method of any one of embodiments 1 to 32, wherein the layered stack is a continuous film or a rolled-up film. Embodiment 34 is the method of any one of embodiments 1 to 32, wherein the layered stack is an un-rolled sheet or plate. Embodiment 35 is the method of any one of embodiments 1 to 34, wherein the first or second or both substrate layers are perforated or the whole layered stack is perforated. Embodiment 36 is the method of any one of embodiments 1 and 4 to 35, wherein at least one or both of the first and second substrate layers are polymeric layers. Embodiment 37 is the method of embodiment 36, wherein the first or second polymeric layer, or both polymeric layers, comprises polyethylene terephthalate (PET), a polycarbonate (PC) family of polymers, polybutylene terephthalate (PBT), poly(1,4-cyclohexylidene cyclohexane-1,4-dicarboxylate) (PCCD), glycol modified polycyclohexyl terephthalate (PCTG), Poly(phenylene oxide) (PPO), polypropylene (PP), polyethylene (PE), polyvinyl chloride (PVC), polystyrene (PS), polyethyleneimine, thermoplastic elastomer (TPE), terephthalic acid (TPA) elastomers, poly(cyclohexanedimethylene terephthalate) (PCT), polyethylene naphthalate (PEN), polyamide (PA), polystyrene sulfonate (PSS), polyether ether ketone (PEEK), or polyetherimide (PEI), or combinations or blends thereof. Embodiment 38 is the method of embodiment 36, wherein the first substrate layer and the second substrate layer each comprise PET. Embodiment 39 is the method of embodiment 36, wherein at least one of the first or second substrate layers is a polymethylmethacrylate (PMMA) layer, polydimethylsiloxane (PDMS) layer, or a thermal release tape. Embodiment 40 is the method of embodiment 39, wherein both of the first and second substrate layers are each one of a polymethylmethacrylate (PMMA) layer, polydimethylsiloxane (PDMS) layer, or a thermal release tape. Embodiment 41 is the method of any one of embodiments 1 to 40, wherein the first and second conductive materials are each graphene electrodes. Embodiment 42 is the method of any one of embodiments 1 to 40, wherein the first and second substrate layers are non-conductive layers or insulators. Embodiment 43 is a conductive material made by the method of any one of claims 1 to 42.

Embodiment 44 is a layered stack comprising a first substrate layer, a first graphene layer attached to the first substrate layer, a metal layer attached to the first graphene layer, a second graphene layer attached to the metal layer, and a second substrate layer attached to second graphene layer. Embodiment 45 is the layered stack of embodiment 44, wherein the first and second substrate layers are polymeric layers. Embodiment 46 is the layered stack of embodiment 45, wherein the first and second polymeric layers are each polyethylene terephthalate layers and the metal layer is a copper layer or a nickel layer. Embodiment 47 is the layered stack of any one of embodiments 44 to 46, wherein the first substrate layer and the first graphene layer are attached together through a first adhesive layer positioned between the first substrate layer and the first graphene layer. Embodiment 48 is the layered stack of embodiment 47, wherein the second substrate layer and the second graphene layer are attached together through a second adhesive layer positioned between the second substrate layer and the second graphene layer. Embodiment 49 is the layered stack of any one of embodiments 47 to 48, wherein the first and second adhesive layers comprise a thermally activated adhesive, a pressure activated adhesive, a solvent activated adhesive, a UV activated adhesive, a plasma active adhesive, or any combination thereof. Embodiment 50 is the layered stack of embodiment 49, wherein the first and second adhesive layers each comprise a thermally activated adhesive. Embodiment 51 is the layered stack of embodiment 50, wherein the thermally activated adhesive is a polyethylene acrylate polymer or copolymer thereof, ethylene vinyl acetate copolymer (EVA), ethylene methyl acrylate copolymers (EMA), ethylene acrylic acrylate (EAA), ethylene ethyl acrylate (EEA), or ethylene methyl acidic acrylate (EMAA), or any combination thereof. Embodiment 52 is the layered stack of any one of embodiments 44 to 51, wherein the first substrate layer and the first graphene layer are attached together by heat, pressure, plasma activation, electrostatic interaction, or any combination thereof. Embodiment 53 is the layered stack of embodiment 52, wherein the second substrate layer and the second graphene layer are attached together by heat, pressure, plasma activation, electrostatic interaction, or any combination thereof. Embodiment 53 is the layered stack of embodiment 52, wherein the second substrate layer and the second graphene layer are attached together through a first adhesive layer positioned between the second substrate layer and the second graphene layer. Embodiment 55 is the layered stack of any one of embodiments 44 to 54, wherein the metal layer includes a catalytic metal. Embodiment 56 is the layered stack of embodiment 55, wherein the catalytic metal is copper (Cu), palladium (Pd), platinum (Pt), ruthenium (Ru), iridium (Ir), cobalt (Co), silver (Ag), gold (Au), germanium (Ge), and nickel (Ni). Embodiment 57 is the layered stack of any one of embodiments 44 to 56, wherein the layered stack is a continuous or a rolled-up film. Embodiment 58 is the layered stack of any one of embodiments 44 to 56, wherein the layered stack is an un-rolled sheet or plate. Embodiment 59 is the layered stack of any one of embodiments 44 to 58, wherein the first or second or both substrate layers are perforated or the whole layered stack is perforated. Embodiment 60 is the layered stack of any one of embodiments 44 and 47 to 59, wherein at least one or both of the first and second substrate layers are polymeric layers. Embodiment 61 is the layered stack of embodiment 60, wherein the first or second polymeric layer, or both polymeric layers, comprises polyethylene terephthalate (PET), a polycarbonate (PC) family of polymers, polybutylene terephthalate (PBT), poly(1,4-cyclohexylidene cyclohexane-1,4-dicarboxylate) (PCCD), glycol modified polycyclohexyl terephthalate (PCTG), Poly(phenylene oxide) (PPO), polypropylene (PP), polyethylene (PE), polyvinyl chloride (PVC), polystyrene (PS), polyethyleneimine, thermoplastic elastomer (TPE), terephthalic acid (TPA) elastomers, poly(cyclohexanedimethylene terephthalate) (PCT), polyethylene naphthalate (PEN), polyamide (PA), polystyrene sulfonate (PSS), polyether ether ketone (PEEK), or polyetherimide (PEI), or combinations or blends thereof. Embodiment 62 is the layered stack of embodiment 60, wherein the first substrate layer and the second substrate layer each comprise PET. Embodiment 63 is the layered stack of embodiment 60, wherein at least one of the first or second substrate layers is a polymethylmethacrylate (PMMA) layer, polydimethylsiloxane (PDMS) layer, or a thermal release tape. Embodiment 64 is the layered stack of embodiment 63, wherein both of the first and second substrate layers are each one of a polymethylmethacrylate (PMMA) layer, polydimethylsiloxane (PDMS) layer, or a thermal release tape. Embodiment 65 is the layered stack of any one of embodiments 44 to 64, wherein a protective layer is attached to the first adhesive layer, the first graphene layer, the metal layer, the second graphene layer, or combinations thereof. Embodiment 66 is the layered stack of embodiment 65, wherein the protective layer is a thermoplastic polymeric film.

Embodiment 67 is a graphene stack comprising a first adhesive layer attached to a first graphene layer, a metal layer attached to the first graphene layer opposite the first adhesive layer, and a second graphene layer attached to the metal layer opposite the first graphene layer. Embodiment 68 is the graphene stack of embodiment 67, wherein a second adhesive layer is attached to the second graphene layer opposite the metal layer. Embodiment 69 is the graphene stack of any one of embodiments 67 to 68, wherein the first and second adhesive layers include a thermally activated adhesive, a pressure activated adhesive, a solvent activated adhesive, a UV activated adhesive, a plasma active adhesive, or any combination thereof. Embodiment 70 is the graphene stack of embodiment 69, wherein the first and second adhesive layers each comprise a thermally activated adhesive. Embodiment 71 is the graphene stack of embodiment 70, wherein the thermally activated adhesive is a polyethylene acrylate polymer or copolymer thereof, ethylene vinyl acetate copolymer (EVA), ethylene methyl acrylate copolymers (EMA), ethylene acrylic acrylate (EAA), ethylene ethyl acrylate (EEA), or ethylene methyl acidic acrylate (EMAA), or any combination thereof. Embodiment 72 is the graphene stack of any one of embodiments 67 to 71, wherein a protective layer is attached to the first adhesive layer, the first graphene layer, the metal layer, the second graphene layer, or any combinations thereof. Embodiment 73 is the graphene stack of embodiment 67, wherein the protective layer is a thermoplastic polymeric film.

Embodiment 74 is a method of making an active material. The method includes (a) obtaining a layered stack that includes a first substrate layer, a first 2-dimensional active material layer attached to the first substrate layer, a metal layer attached to the first 2-dimensional layer, a second 2-dimensional layer attached to the metal layer, and a second substrate layer attached to second 2-dimensional layer; (b) removing the metal layer from the layered stack; and (c) obtaining two active materials, wherein the first active material comprises the first substrate layer attached to the first 2-dimensional layer, wherein the second active material includes the second substrate layer attached to the second 2-dimensional layer, and wherein the first and second 2-dimensional layers are active layers. Embodiment 75 is the method of embodiment 74, wherein the 2-dimensional active layer is graphene, patterned graphene, functionalized graphene, or h-BN, MoS₂, NbSe₂, WS₂, NiS₂, MoSe₂, WSe₂, VSe₂, TiS₂.

Embodiment 76 is a catalyst comprising the conductive material produced from the methods of any one of embodiments 1 to 75. Embodiment 77 is a lubricant comprising the conductive material produced from the methods of any one of claims 1 to 75. Embodiment 78 is a container comprising the conductive material produced from the method of any one of embodiments 1 to 75. Embodiment 79 is the container of claim 78, wherein the container is a storage container. Embodiment 80 is the container of claim 78, wherein the container includes gas, liquid or both. Embodiment 81 is an optoelectronic device, a battery, a capacitor, or a sensor comprising the conductive material as produced form the methods of any one of embodiments 1 to 75.

The term “about” or “approximately” are defined as being close to as understood by one of ordinary skill in the art, and in one non-limiting embodiment the terms are defined to be within 10%, preferably within 5%, more preferably within 1%, and most preferably within 0.5%.

The term “substantially” and its variations are defined as being largely but not necessarily wholly what is specified as understood by one of ordinary skill in the art, and in one non-limiting embodiment substantially refers to ranges within 10%, within 5%, within 1%, or within 0.5%.

The terms “inhibiting” or “reducing” or “preventing” or “avoiding” or any variation of these terms, when used in the claims and/or the specification includes any measurable decrease or complete inhibition to achieve a desired result.

The term “effective,” as that term is used in the specification and/or claims, means adequate to accomplish a desired, expected, or intended result.

The use of the word “a” or “an” when used in conjunction with the term “comprising” in the claims or the specification may mean “one,” but it is also consistent with the meaning of “one or more,” “at least one,” and “one or more than one.”

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

The methods of the present invention can “comprise,” “consist essentially of,” or “consist of” particular ingredients, components, compositions, etc. disclosed throughout the specification. With respect to the transitional phase “consisting essentially of,” in one non-limiting aspect, a basic and novel characteristic of the methods, layered stacks, and graphene stacks of the present invention are their ability to allow for increased production of graphene laminates, graphene electrodes, and graphene interconnects. For example, a doubling of the production output can be achieved by using the features of the present invention.

Other objects, features and advantages of the present invention will become apparent from the following figures, detailed description, and examples. The drawings may not be to scale. It should be understood, however, that the figures, detailed description, and examples, while indicating specific embodiments of the invention, are given by way of illustration only and are not meant to be limiting. Additionally, it is contemplated that changes and modifications within the spirit and scope of the invention will become apparent to those skilled in the art from this detailed description.

### BRIEF DESCRIPTION OF THE DRAWINGS

FIG. 1A is a 2-D cross-sectional representation of a layered stack of the present invention.

FIG. 1B is a 2-D cross-sectional representation of a layered stack of the present invention having adhesive layers.

FIG. 2A is a schematic of a method of the present invention for production of graphene electrodes.

FIG. 2B is a schematic of a method of the present invention for production of graphene electrodes having an adhesive layer.

FIGS. 3A-3F are schematics of embodiments of methods for forming layered stacks of the present invention.

FIGS. 4A-4C are schematics of embodiments of the present invention for making layered stacks starting with a stack that includes adhesive layers, graphene layers and a metal layer.

FIG. 5 is a schematic of a non-limiting embodiment of a system to make graphene laminates in accordance with the methods of the present invention.

FIGS. 6A and 6B are schematics of embodiments of the present invention of directly transferring a graphene layer onto a single substrate layer.

FIG. 7 is a schematic of an embodiment of the present invention of directly transferring a single graphene layer onto a single substrate layer using a laminating process.

FIG. 8A is a schematics of an embodiment of the present invention for making graphene laminates containing perforated substrates.

FIG. 8B is a schematic of an embodiment of the present invention for making graphene laminates with perforated graphene layers.

FIG. 8C is a schematic of an embodiment of the present invention for making graphene laminates containing perforated substrates and adhesive layers.

FIG. 8D is a schematic of an embodiment of the present invention for making graphene laminates containing perforated substrates, perforated adhesive layers, perforated graphene, and perforated metal layers.

FIG. 9 is a schematic of an embodiment of the present invention for making graphene laminates with patterned or functionalized graphene.

FIG. 10A is an image of a graphene laminate produced by the methods of the present invention close to the surface of an object.

FIG. 10B is an image of a graphene laminate produced by the methods of the present invention about 20 cm from the surface of an object.

FIG. 11 is a schematic of a method of the present invention for making two multilayered graphene laminates using an electrochemical etching solution.

### DETAILED DESCRIPTION OF THE INVENTION

The present invention allows for the simultaneously transfer of two graphene layers comprised on the opposite sides of a metal layer to two separate substrates, thereby producing two graphene laminates at substantially the same time. The direct transfer of these graphene layers can be performed with or without the need for pre-conditioning steps (e.g., use of intermediary supporting layers such as PMMA or PDMS), thereby providing for a more cost efficient and scalable production process. Still further, the use of both graphene layers in the transfer process substantially increases the production output (e.g., from one graphene laminate to two graphene laminates). The resulting graphene laminates can be used in a wide array of applications ranging from conductive electrodes or interconnects in electronic devices.

These and other non-limiting aspects of the present invention are discussed in detail below with reference to the Figures.

### A. Stacks

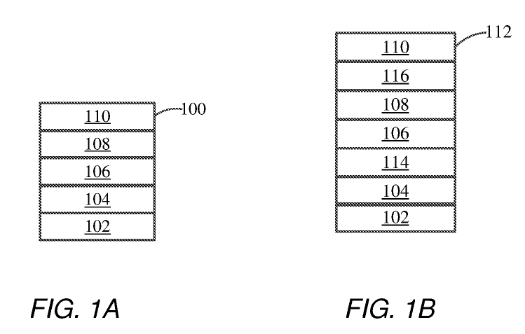

FIG. 1A is a schematic of layered stack 100 of the present invention. The layered stack 100 can be obtained using the methods described throughout this specification. The stack 100 can be a layered stack that includes the first substrate layer 102, the first conductive material layer 104, the metal layer 106, the second conductive material layer 108, and the second substrate layer 110. The first and/or second conductive material layers can be the same or different. Examples of conductive or active materials include graphene and the other active materials described throughout the Specification. While graphene is used in describing the Figures, it should be understood that other conductive or active materials can be used within the scope of the present invention. The metal layer 106 is in between the first graphene layer 104 and the second graphene layer 108. The first and second substrate layers 104 and 108 can be any material described throughout this Specification. In some embodiments, the substrate is flexible. In some aspects, the substrate can be any polymer or polymer blend described throughout this Specification. In a non-limiting example, the substrate can include PET. The metal layer can be a catalytic metal. Non-limiting examples of a metal are copper (Cu), platinum (Pt), palladium (Pd), ruthenium (Ru), iridium (Jr), cobalt (Co), silver (Ag), gold (Au), germanium (Ge), and nickel (Ni). A preferred metal is copper. In some aspects of the invention the substrate is PET and the metal layer is copper. The metal layer 106 is a support layer for the graphene on which the graphene is produced by chemical vapor deposition. Copper foil of 1 nm to 10 mm thickness can be used to provide mechanical stability for the graphene and the ability to etch the metal in subsequent steps described herein. The graphene layers 104 and 108 can be grown on the copper foil using, for example, chemical vapor deposition methods. In some aspects of the invention, the metal layer 106 containing the first graphene layer 104 and the second graphene layer 108 can be purchased from a commercial supplier (for example, Graphene Supermarket, New York). In some aspects, at least one of the first or second substrate layers 102 and 110 is a polymethylmethacrylate (PMMA) layer, polydimethylsiloxane (PDMS) layer, or a thermal release tape.

FIG. 1B is a schematic of layered stack 112 of the present invention. The layered stack 112 can be obtained using the methods described throughout this specification. The stack 112 can be a layered stack that includes a first substrate layer 102, a first adhesive layer 114, and a first graphene layer 104. The first adhesive layer 114 can be between and in contact with the first substrate layer 102 and the first graphene layer 104. In some aspects of the invention, the first adhesive layer 114 substantially covers the surface of the first substrate layer 102 and the surface of the first graphene layer 104. In certain aspects of the invention first adhesive layer 114 is attached to first substrate 102 and first graphene layer 104. The metal layer 106 is in between the first graphene layer 104 and a second graphene layer 108. A second adhesive layer 116 can be between the second graphene layer 108 and the second substrate layer 110. The second adhesive layer 116 can be in contact with, and/or attached to, the second substrate layer 110 and the second graphene layer 108. In some aspects of the invention, the second adhesive layer 116 substantially covers the surface of the second substrate layer 110 and the surface of the second graphene layer 108. The first and second substrate layers 102 and 110 can be any flexible material compatible with an adhesive material. The flexible material can include any polymer or polymer blend described throughout this Specification. In a non-limiting example, the substrate can include PET. The first and second adhesive layers 114 and 116 can be any thermally activated adhesives, pressure activated adhesives, solvent activated adhesives, or plasma active adhesives described throughout this Specification. The first adhesive layer 114 can be the same or different from the second adhesive layer 116. In a preferred embodiment, the first and second adhesive layers adhesive layers can include ethyl vinyl acetate. The metal layer 106 and the graphene layers 104 and 108 can be as described above and throughout this Specification.

### B. Method of Making Graphene Electrodes

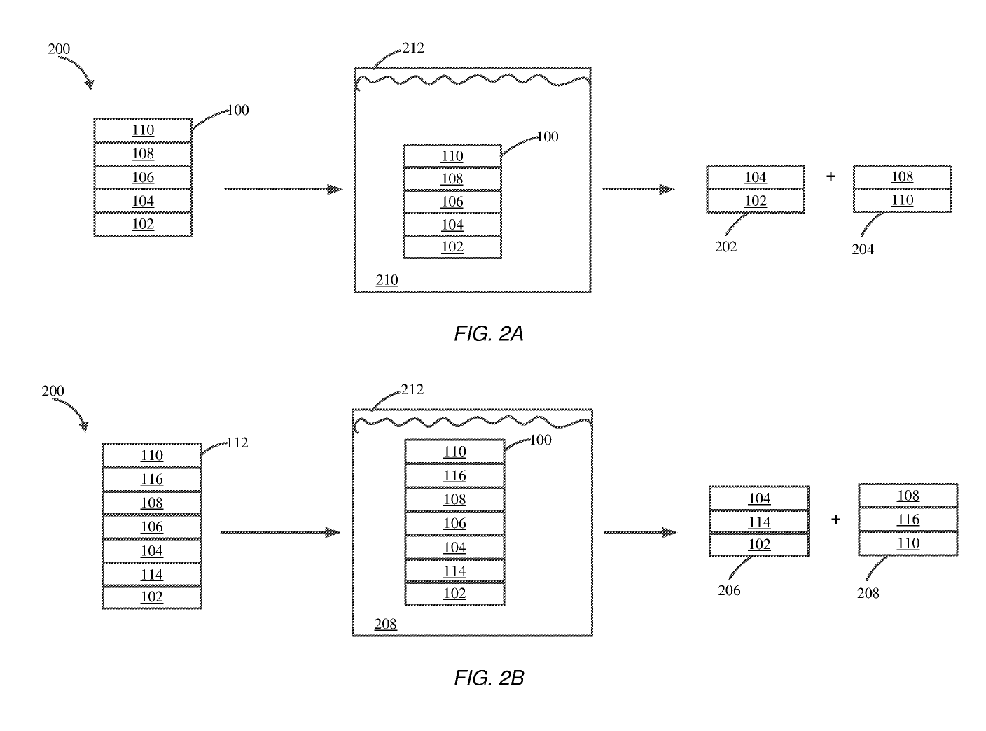

FIGS. 2A and 2B are schematics of embodiments of making graphene electrodes from the layered stack 100 or the layered stack 112. The method 200 can include obtaining a layered stack 100 or the layered stack 112, and subjecting the stack to a process that removes the metal layer 106 from the layered stack 100 or the layered stack 112 to produce two graphene electrodes 202 and 204 shown in FIG. 2A or the two graphene electrodes 206 and 208 shown in FIG. 2B. As shown in FIGS. 2A and 2B, the stacks 100 and 112 can be put in contact with an etching solution 210 in a container 212. The etching solution 210 can be any suitable solution that can remove the underlying metal (for example, copper) from the graphene, leaving the surface of the graphene exposed, and forming first graphene electrode 202 and second graphene electrode 204 shown in FIG. 2A or first graphene electrode 206 and the second graphene electrode 208 as shown in FIG. 2B. Non-limiting examples of etching solutions include 1M to 5M aqueous ferric chloride (FeCl₃), hydrochloric acid (HCl), nitric acid (HNO₃), 1M aqueous ferric nitrate (Fe(NO₃)₃) and (NH₄)₂S₂O₈. The etching solution 210 can be heated at different temperatures from 25 to 65° C., and the stack 100 can be immersed into the etching solution until the metal visibly disappears. In some embodiment the metal can be removed using electrochemical etching solution. In a non-limiting example, the stack 100 can be immersed in an aqueous etching solution of ammonium persulfate. A voltage of −5V can be applied between the stack and a platinum electrode. As current flows between the stack and the platinum electrode, hydrogen is evolved from reduction of the water, and generates air bubbles. The air bubbling can delaminate and partially etch the copper, which allows for the complete detachment of the copper from the graphene layer.

As shown in FIG. 2A, once the metal dissolves, the stack 100 separates into the first graphene electrode 202 and the second graphene electrode 204. The two electrodes 202 and 204 can be removed from the etching solution 210. The first graphene electrode 202 can include the first substrate layer 102, the first graphene layer 104. The second graphene electrode 204 can include the second substrate layer 110 and the second graphene layer 108. The first and second electrodes 202 and 204 can be transparent and are conductive (for example, each electrode can have a sheet resistance of 1.5 to 2 kilo-ohm per square (kΩ/sq)). As shown in FIG. 2B, once the metal dissolves, the stack 112 separates into the first graphene electrode 206 and the second graphene electrode 208. The two electrodes 206 and 208 can be removed from the etching solution 210. The first graphene electrode 206 can include the first substrate layer 102, the first graphene layer 104, and the first adhesive layer 114 between the first substrate layer 102 and the first graphene layer 104. The second graphene electrode 208 can include the second substrate layer 110, the second graphene layer 108, and the second adhesive 116 layer positioned between the second substrate layer 110 and the second graphene layer 108. The electrodes 206 and 208 can be transparent and are conductive (for example, each electrode can have a sheet resistance of 1.5 to 2 kΩ/sq.). Other techniques to remove the metal are contemplated, for example, removal using electrochemical etching or mechanical delamination.

### C. Formation of Stacks

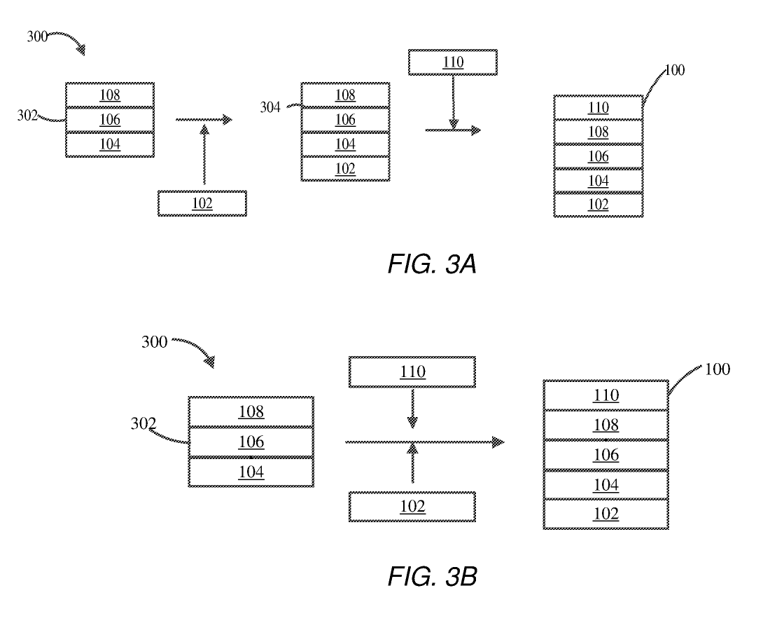

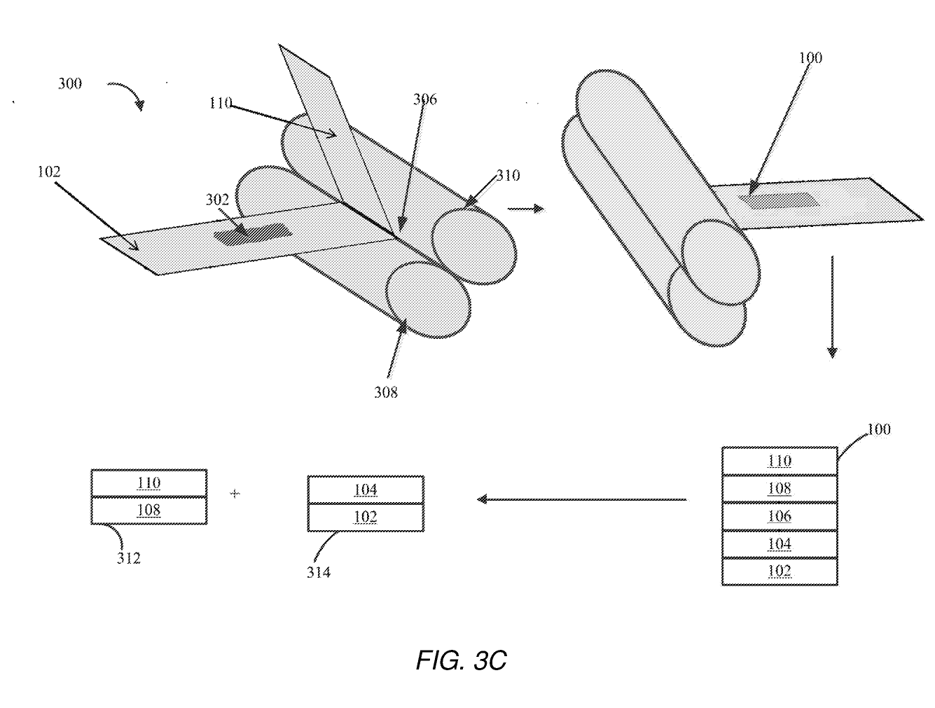

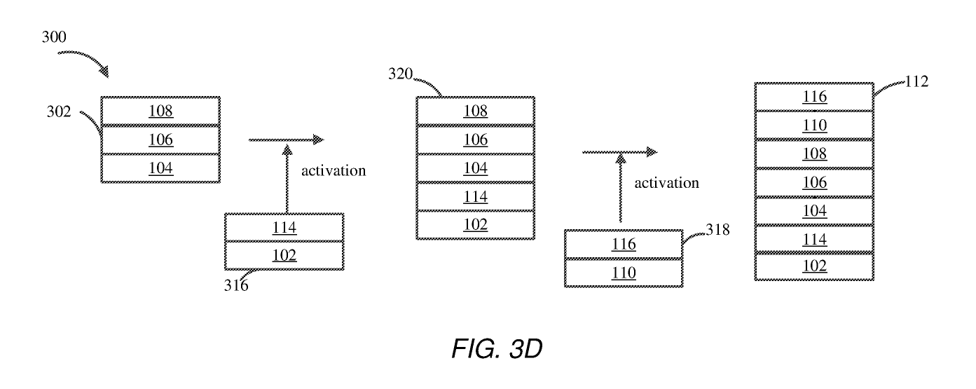

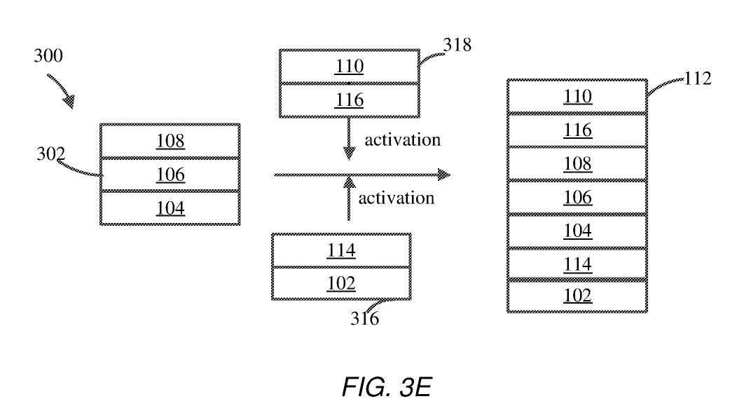

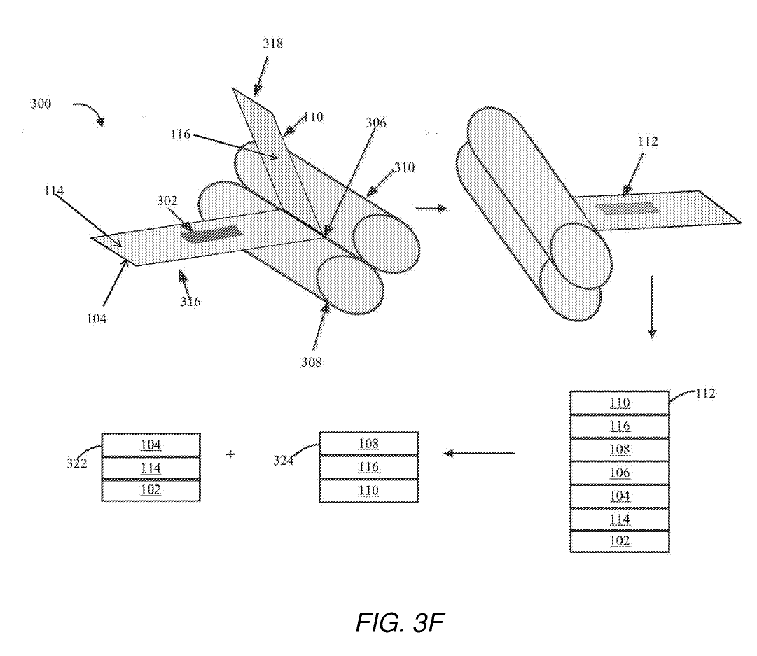

The layered stack 100 or the layered stack 112 can be obtained by directly transferring one or more graphene layers to two substrates. FIGS. 3A, 3B, and 3C are schematics of embodiments of method 300 for directly transferring graphene layers from a metal layer to two substrate layers, and thereby, forming the layered stack 100. FIGS. 3D, 3E and 3F are schematics of embodiments of method 300 for directly transferring graphene layers from a metal layer to two substrate layers, and thereby, forming the layered stack 112. In method 300, a graphene stack 302 is obtained. The graphene stack 302 can include first graphene layer 104, metal layer 106, and second graphene layer 108. As shown in FIG. 3A, a first substrate 102 is obtained and a second substrate 110 is obtained. The graphene stack 302 and the first substrate 102 can be subjected to conditions that connects the first graphene layer 104 to the first substrate to form a layered stack 304. Layered stack 304 includes first substrate 102, graphene layer 104 and metal layer 106, and second graphed layer 108. To attach the substrate and the graphene stack 304, they can be subjected to a cold roll-to-roll process, a hot roll-to-roll process, laminating conditions, heat, pressure, plasma activation, electrostatic interaction or any combination thereof. The second substrate 110 may then be attached to the second graphene layer 108 of the second substrate in a likewise fashion to form stack 100. As shown in FIG. 3B, substrates 102 and 110 are simultaneously coupled or attached to the graphene stack 302. Referring to FIG. 3C, the layered stack 100 can be made using a heat and pressure process. The first substrate 102 and the second substrate 110 can be joined at one end to form a pouch, and the graphene stack 302 can be inserted into the pouch. In some embodiments, substrates 102 and 110 are polymeric sheets joined at one end. In some embodiments, the substrates 102 and 110 can have a thickness of 1 nm to 10 mm. In some embodiments, substrates 102 and 110 can be PET sheets that do not contain adhesive. In some aspects, the substrate layers 102 and 110 have the same or different thicknesses. The ends of substrate 102 and the substrate 110 are passed through a nip 306 that is between a lower roller 308 and an upper roller 310. Lower roller 308 and upper roller 310 can be cylindrical counter-rotating calendar rolls positioned to define there between the nip 306. Movement of the rolls 308 and 310 pulls or moves the ends of substrates 102 and 110 through the nip 306. The substrates 102 and 110 and graphene stack 302 pass through the nip 306 with graphene stack 302 between the first substrate 102 and the second substrate 110. The stacks are compressed together in the thickness direction as they pass through the nip 306. The heat of the rollers 308 and 310 can each be set to achieve a particular activation for the substrates. In some aspects the heat and/or pressure of the rollers 308 and 310 are set to achieve a particular activity of the produced graphene material and/or a targeted sheet resistance a graphene electrode. The applied heat may also be chosen such that substrates 102 and 110 soften during the process. The simultaneous application of heat, and, in some instances pressure, allows for the first graphene layer 104 and the second graphene layer 108 to sufficiently attach to the first substrate layer 102 and second substrate layer 110, respectively, and, thereby form stack 100. The stack 100 is then subjected to conditions to remove metal layer 106 as described in FIG. 2A and throughout this Specification to form the two graphene laminates 312 and 314.

As shown in FIG. 3D, a first substrate stack 316 is obtained, and can include first substrate layer 102 and first adhesive layer 114. A second substrate stack 318 is obtained, and can include second substrate layer 110 and second adhesive layer 116. The graphene stack 302 and first substrate stack 316 can be subjected to conditions that activates the first adhesive layer 114 so that the two stacks adhere together to form the layered stack 320. In some embodiments, the stacks may be subjected to a cold roll-to-roll process, a hot roll-to-roll process, laminating conditions, or heat and pressure. During the process, the first adhesive layer 114 can be activated by heat, UV, contact with a solvent, high-voltage electric discharge, plasma, or any combination thereof. Upon contact with the activated first adhesive layer 114, the first graphene layer 104 adheres or attaches to stack 302 to form stack 320. The second adhesive layer 116 in stack 318 may then be contacted with the second graphene layer 108 of second substrate stack 320 in a likewise fashion to form stack 112. As shown in FIG. 3E, substrate stacks 316 and 318 are simultaneously coupled to the graphene stack 302. In FIG. 3E, adhesive layers 114 and 116 are activated simultaneously, or substantially simultaneously, and then contacted with graphene layers 104 and 108 to produce layered stack 112. Referring to FIG. 3F, layered stack 112 is made by activating adhesive layers 114 and 116 using laminating process to form layered stack 112. The first stack 316 and the second stack 318 can be joined at one end to form a pouch, and the graphene stack 302 can be inserted into the pouch. In some embodiments, stacks 316 and 318 are polymeric sheets coated with an adhesive and joined at one end. In some embodiments, the stacks can have a thickness of 2 nm to 20 mm. For example, stacks 316 and 318 can be PET sheets coated with adhesive having a thickness of about 75 μm. In some aspects, the substrate layers 102 and 110 have the same or different thicknesses. The thickness of substrate layers 102 and 110 can be from 1 nm to 10 mm. The thickness of adhesive layers 114 and 116 can be the same or different. The thickness of adhesive layers 114 and 116 can be from 1 nm to 10 mm. The ends of first stack 316 and second stack 318 are passed through a nip 306 as previously described for FIG. 3C. As stacks 302, 316 and 318 pass through the nip 306, the stacks are compressed together in the thickness direction as they pass through the nip. In embodiments, where a pressure active adhesive is used, the pressure applied to the rollers 308 and 310 may be set to activate the adhesive. In embodiments where the first adhesive layer 114 or the second adhesive layer 116 are heat activated adhesives, the rollers 308 and/or 310 are heated. The heat of the rollers 308 and 310 can each be set to achieve a particular activation for the adhesive. In some aspects the heat and/or pressure of the rollers 308 and 310 are set to achieve a particular activity of the produced graphene material and/or a targeted sheet resistance of the graphene electrode. In the heating process, the first stack 316 and the second stack 318 are heated, for example, to a temperature that is greater than the melt point temperatures or the Vicat softening temperatures (for example, 60 to 85° C.) of the first thermal adhesive layer 114 and the second thermal adhesive layer 116 and less than the melting point of the first substrate layer 102 and the second substrate layer 110 as they pass through the nip 306. The applied heat may also be chosen such that substrates 102 and 110 soften during the process. The simultaneous application of heat and in some instances pressure, allows for the first graphene layer 104 and the second graphene layer 108 to sufficiently adhere or attach to the first adhesive layer 114 and the second adhesive layer 116, respectively, and, thereby form stack 112. In embodiments where a solvent activated adhesive is used, the activating solvent (for example, an organic compound, toluene, hexane, acetone, ethyl acetate, etc.) is applied to the adhesive layers 114 and 116 prior to passing the stacks 302, 316 and 318 through nip 306. In embodiments where the adhesive is a UV-activated, a plasma activated adhesive, or a high-voltage activated adhesive, the adhesive layers 114 and 116 can be activated by the light, plasma or voltage as the stacks are passing through nip 306. In some embodiments, the UV-light source, voltage source, or plasma source is located in the rollers 306 and 308, or proximate to the rollers. The stack 112 is then subjected to conditions to remove metal layer 106 as described in FIG. 2 and throughout this Specification to form the two graphene laminates 322 and 324.

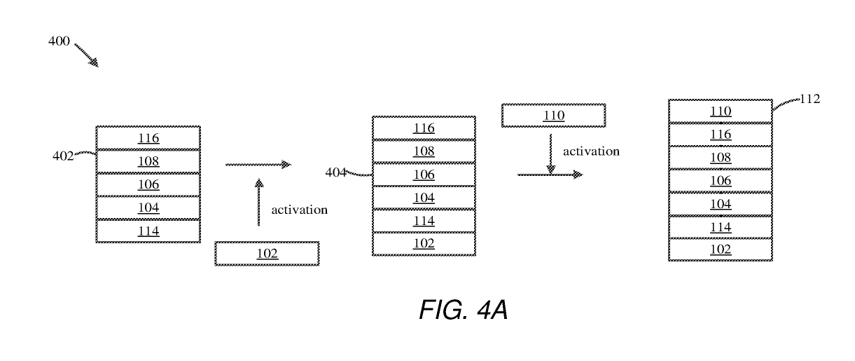

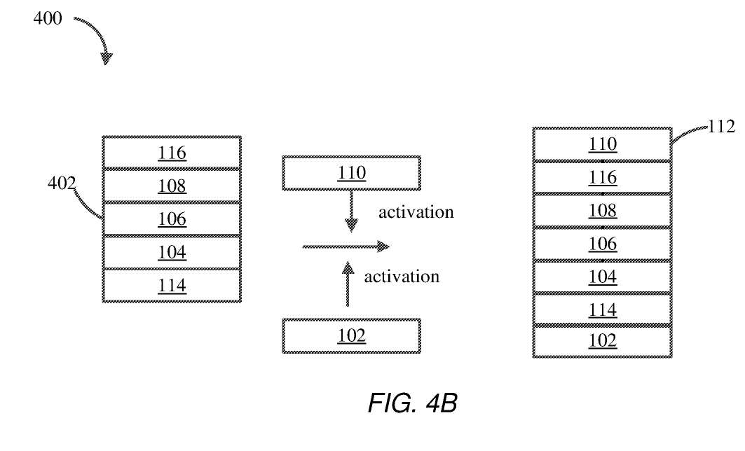

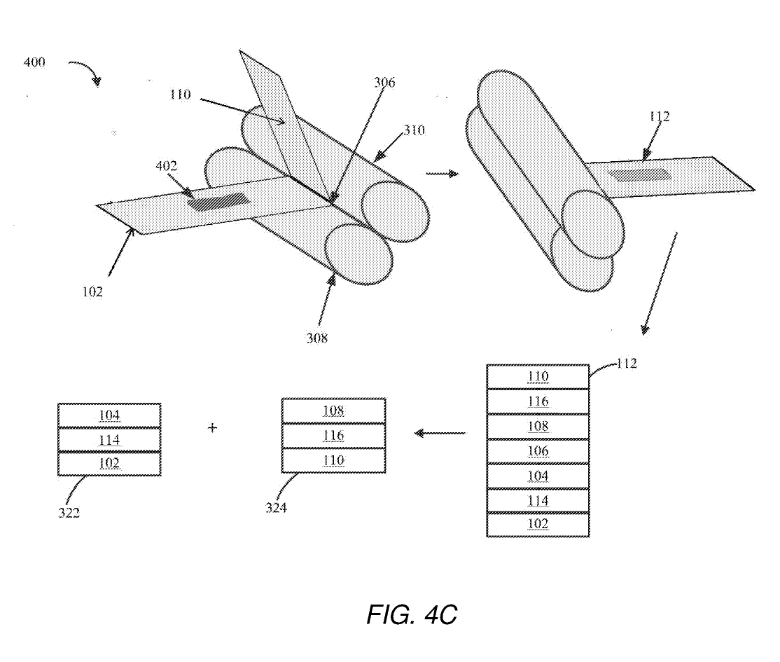

In some aspects of the invention of forming layered stacks, the first and second adhesive layers 114 and 116 are applied to first and second graphene layers 104 and 108 to form a graphene layer/adhesive layer stack. FIGS. 4A through 4C are schematics of methods of making the stack 112 from the graphene layers, metal layer, adhesive layers stack 402. In methods 400, the stack 402 can include first adhesive layer 114, first graphene layer 104, metal layer 106, second graphene layer 108, and second adhesive layer 116. As shown in FIG. 4A, the stack 402 and first substrate layer 102 can be subjected to conditions that adheres or attaches the substrate layer to the stack 402 to form the stack 404. The conditions that the stack 402 and the substrate layer 102 can be subjected to can be a roll-to-roll process, a roll-to-roll laminating process, or heat and pressure as described previously and throughout this Specification. During the adhesion process, the adhesive layer 114 can be activated by heat, UV, solvent, high-voltage electricity, or plasma as described previously and throughout this Specification. Upon contact with the active adhesive layer 114, the substrate layer 102 adheres or attaches to stack 402 to form stack 404. The stack 404 may then be adhered or attached to the second substrate layer 110 in a likewise fashion to form stack 112. As shown in FIG. 4B, substrate layers 102 and 110 are simultaneously coupled to the stack 402. Although first layer 102 and second layer 110 are shown as two separate layers, the layers maybe two layers joined at one edge as depicted in FIG. 4C, and processed in a similar manner as described for FIG. 3F.

### D. Roll-to-Roll Laminating System for Production of Two Graphene Laminates

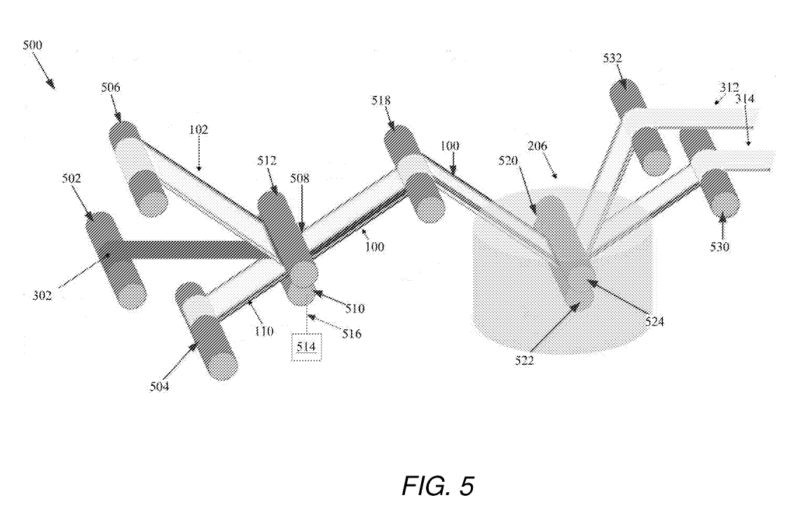

FIG. 5 is a schematic of a non-limiting embodiment of a system 500 to make graphene laminates in accordance with the methods of the present invention. In particular, FIG. 5 is a schematic of a non-limiting roll-to-roll system 500 that can be used to produce graphene laminates of the present invention, for example graphene laminates 312, 314, 322 and 324. The system 500 includes a first supply roll 502, a second supply roll 504, and a third supply roll 506. The system shown in FIG. 5, is to produce graphene laminates 312 and 314, however, it should be understood that the supply rolls 502, 504 and 506 can provide graphene layers—metal layers—adhesive layers stack as described in FIGS. 3A-F and 4A-C. As shown in FIG. 5, second supply roll 502 can provide graphene stack 302. The second supply roll 504 and the third supply roll 506 can provide the first substrate stack 102 and the second substrate layer 110, respectively. The first supply roll 502 is positioned between the second supply roll 504 and the third supply roll 506. As shown in FIG. 5, each stack is formed prior to being used, however, it should be understood that each supply roll 502, 504, and 506 can be part of a take-up roll from one or more systems (e.g. roll-to-roll systems) that produce each stack and feed into system 500 and/or may be rolls of commercially prepared materials. For example, roll 502 can be a commercial roll of graphene on copper foil, and rolls 504 and 506 can be commercially prepared rolls of a polymeric substrate coated with a thin layer of adhesive or polymeric substrate. Stacks 302, 102, and 110 are passed through a nip 508 that is between a heated lower roller 510 and a heated upper roller 512. Nip 508 is formed at the interface of counter-rotating rollers 510 and 512. As shown in FIG. 5, rollers 510 and 512 may be counter-rotating, but any type of roll-to-roll configuration can be used in the system as long as the rolls are capable of heating and pressing three stacks together at once. The rollers 502, 504 and 506 can pass through the nip 508 with graphene stack 302 between the first substrate stack 102 and the second substrate layer 110. A pneumatic cylinder 514 can be connected via a rod 516 to the axle of the heated idler roller 510 to maintain a desired pressure on the stacks 302, 102, and 110 when passing through the nip 508. The heat of the rollers 510 and 512, and the pressure applied can each be set to achieve a particular activation for the adhesive of the produced graphene material and/or a targeted sheet resistance of the graphene material. In passing through nip 508, first substrate stack 102 and second substrate layer 110 are heated, for example, to a temperature that is greater than the melt point temperatures or the Vicat softening temperatures (for example, 60 to 85° C.) of the substrates and less than the melting point of the substrates as they pass through the nip 508. The simultaneous application of heat and pressure allows for the first graphene layer 104 and the second graphene layer 108 to sufficiently activate the substrates such that the graphene layers adhere or attach to the first substrate layer 102 and second substrate layer 110, respectively, and form stack 100. In yet another embodiment, a stack that includes the first thermal adhesive layer 114, first graphene layer 104, metal layer 106, and second graphene layer 108, second adhesive layer 116, first substrate layer 102 and the second substrate layer 110 can be subjected to the process described in FIG. 5 to produce stack 112. It should also be understood that the process or rollers 510, 512 may be modified to include sources of UV light, voltage, plasma or solvent that can used to activate the corresponding adhesive layers (i.e., a UV-activated adhesive, a solvent activated adhesive, etc.). In some aspects, a sprayer may be positioned proximate the supply rolls and apply a set amount of solvent to the adhesive layer as the adhesive layer is moving towards or into nip 508. Alternatively, the upper roller 512 is not heated and the lower roller 510 is heated, thereby providing heat to the only to second substrate layer 110 or vice versa.

As the stack 100 passes through nip 508 it is collected onto a take-up roll 518. Take-up roll 518 provides the stack 100 into nip 520 that is between lower roller 522 and upper roller 524 positioned in etching solution 210. Lower roller 522 and upper roller 524 move in opposite directions which moves stack 100 through nip 520. As stack 100 passes through nip 520, contact with the etching solution 210 is sufficient to remove metal layer 106 from stack 100, and thereby, form first graphene laminate 312 and second graphene laminate 314. The speed of rollers 522 and 524 may be adjusted such that the stack 100 moves through etching solution 210 for a time sufficient to allow removal of all, or substantially all, of the metal layer 106. Other techniques to remove the metal are contemplated, for example, electrochemical etching or mechanical delamination. In some embodiment the metal can be removed using electrochemical etching solution. In a non-limiting example, the stack 100 can be rolled through an aqueous etching solution of ammonium persulfate. A voltage of −5V can be applied between the stack and a platinum electrode. As current flows between the stack and the platinum electrode, hydrogen is evolved from reduction of the water, and generates air bubbles. The air bubbling can delaminate and partially etch the copper, which allows for the complete detachment of the copper from the graphene layer. As the graphene laminates 312 and 314 leave etching solution 210 they are collected onto a first take-up roll 530 and second take-up roll 532, respectively. The graphene laminates 312 and 314 can be transparent and have sheet resistance suitable for use as electrodes (for example, a sheet resistance of 1.5 to 2 kΩ/sq.). Also, the produced graphene laminates 312 and 314 can then be feed into another roll-to-roll process to provide a protective layer for the graphene stacks during shipping or storage. In some embodiments, the protective layer is added to the substrate, graphene layer and/or adhesive layer prior to or during the roll-to-roll process. In some embodiments, a protective layer is attached to the first adhesive layer, the first graphene layer, the second adhesive layer, the second graphene layer, or combinations thereof. Non-limiting examples of protective layers include polyethylene films, low-density polyethylene films, linear low-density polyethylene films, medium-density polyethylene films, high-density polyethylene films, ultra-high-molecular-weight polyethylene films, etc. The produced graphene laminates can be used as electrodes in electronic devices, in solar cells or systems, or other devices that require conductive materials. In some embodiments, the graphene laminates can be feed to another roll-to-roll process to provide one or more dopants to the graphene laminate through an immersion process, a spray process, or an evaporation process. Non-limiting examples of dopants include AuCl₃, HNO₃, bis(trifluoromethanesulfonyl)amide ((CF₃SO₂)₂NH, (TFSA)), SOCl₃, tetracyanoquinodimethane (TCNQ), (F₄)TCNQ, FeCl₃, SF₆, SF₄ or MoF₆.

### E. Direct Transfer of a Graphene Layer to a Single Substrate Layer

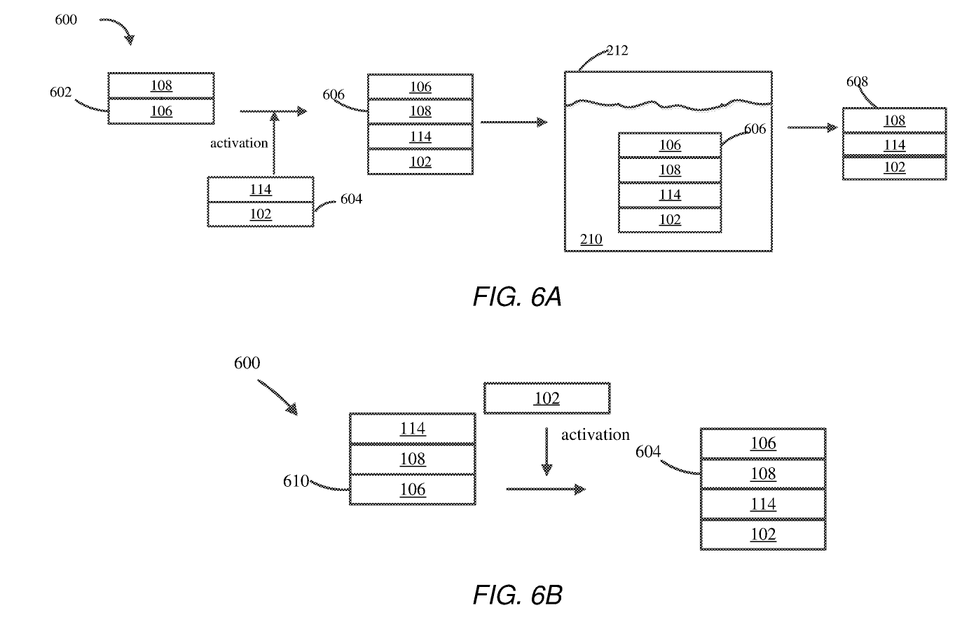

In another aspect of the invention, a method of directly transferring one graphene layer from a metal layer to one substrate layer is described. FIGS. 6A and 6B are schematics that depict the direct transfer of one graphene layer onto one single substrate layer. In FIG. 6A, a graphene stack 602 can include metal layer 106 and graphene layer 108. The substrate stack 604 can include substrate layer 102 and adhesive layer 114. As shown in FIG. 6A, the graphene stack 602 and the substrate stack 604 can be subjected to conditions (e.g., activated) that adhere or attach the two stacks together to form a stack 606. Activation conditions can include subjecting the stacks to a heated roll-to-roll process, a cold roll-to-roll process, laminating conditions, or heat and pressure. During the process, the adhesive layer 114 can be activated by heat, UV, contact with a solvent, plasma, or high-voltage electricity. Upon contact with the activated adhesive layer 114, the graphene layer 108 adheres or attaches to stack 604 to form stack 606. The stack 606 can be subjected to a metal removal process described throughout the Specification to remove the metal layer 106. The stack 606 can be put in contact with an etching solution 210 to remove the metal layer, and thereby, forming the graphene laminate 608. The stack 608 can include substrate layer 102, adhesive layer 114 and graphene layer 108. As shown in FIG. 6B, a stack 610 can include the metal layer 106, the graphene layer 108, and the thermal adhesive layer 114. The stack 610 and substrate 102 layer can be subjected to conditions that adhere the stack and layer together to form a stack 606, which can then be subjected to conditions previously described to remove metal layer 106, and, thereby form graphene laminate 608. The graphene laminate 608 can be used as a graphene electrode or in other applications suitable for flexible graphene materials. It should be understood that the stack 302, that includes the first graphene layer 104, the metal layer 106 and the second graphene layer 108, can be used instead of stack 602, to obtain the same result. In certain instances, other 2D materials can be used instead of the graphene layers. In some embodiments, the substrate layer 102 is attached directly to the graphene stack, or another 2D material stack, without the adhesive layer, by a cold roll-to-roll process, a hot roll-to-roll process, laminating conditions, heat, pressure, plasma activation, electrostatic interaction or any combination thereof.

### F. Laminating System for Production of One Graphene Laminate

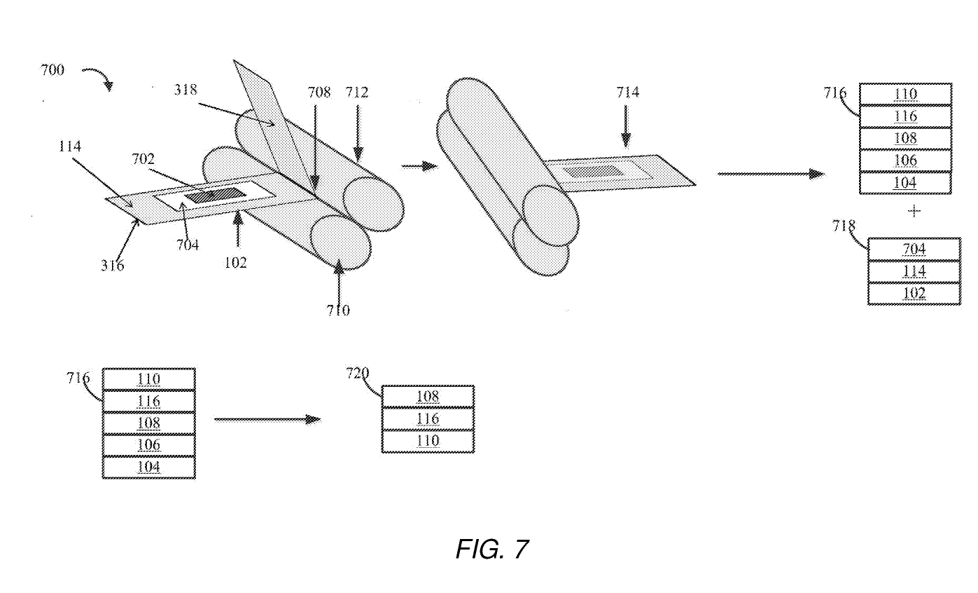

In another aspect of the invention, a method of directly transferring one graphene layers from a metal layer to a substrate layer using a lamination process is described. FIG. 7 is a schematic that depicts the direct transfer of a single graphene layer onto a single substrate layer using a laminating process. In FIG. 7, the graphene stack 702 can be positioned on protective material 704, which is between the graphene stack 702 and substrate stack 316. The graphene stack 702 can include the graphene layer 104, the metal layer 106 and the graphene layer 108. Substrate stack 316 can include adhesive layer 114 and substrate layer 102, and substrate stack 318 can include adhesive layer 116 and substrate layer 110. Stacks 316 and 318 can be joined at one end to form a pouch and the stack 702 can be inserted into the pouch. In some embodiments, substrate stacks 316 and 318 are polymeric sheets homogenously coated with a heat activated adhesive and joined at one end. The ends of first substrate stack 316 and second substrate stack 318 are passed through a nip 708 that is between a heated lower roller 710 and a heated upper roller 712. Lower roller 710 and upper roller 712 each move in opposite directions which pulls, or moves, the ends of first substrate stack 316 and second substrate stack 318 through the nip 708. The stacks 702, 316 and 318 pass through the nip 708 with graphene stack 702 between the first substrate stack 316 and the second substrate stack 318. The heat of the rollers 710 and 712, and the pressure applied can each be set to achieve a particular activation for the adhesive of the produced graphene material and/or a targeted sheet resistance of the graphene material as described throughout this Specification. Upon contact with the active adhesive layer 116 of stack 318, the graphene layer 108 adheres to stack 318 and forms stack 714. Due to the protective material 704, graphene layer 104 is inhibited from adhering to stack 316. The portions of stack 316 and stack 318 that are not in contact with the protective material or the graphene stack 702 adhere together under the laminating conditions. Stack 714 includes first substrate layer 102, first adhesive layer 114, protective material 704, first graphene material 104, metal layer 106, second graphene layer 108, second adhesive layer 116, and second substrate layer 110. Stack 714 can be separated into a stack 716 and a stack 718. In some embodiments, the stack 714 can be cut inside the borders of the stack 702. Stack 716 can include first graphene layer 104, metal layer 106, second graphene layer 108, second adhesive layer 116, and second substrate layer 110. Stack 718 can include first substrate layer 102, first adhesive layer 114, and protective material 704. The stack 716 can be subjected to a metal removal process to remove the metal layer 106. The stack 716 can be immersed in an the etching solution 210 or subjected to other metal removal processes as previously described to remove the metal layer 106, and thereby, form the graphene laminate 720. It should be understood that stack 702 can be substituted for stacks 302 and 602.

### G. Perforated Layers

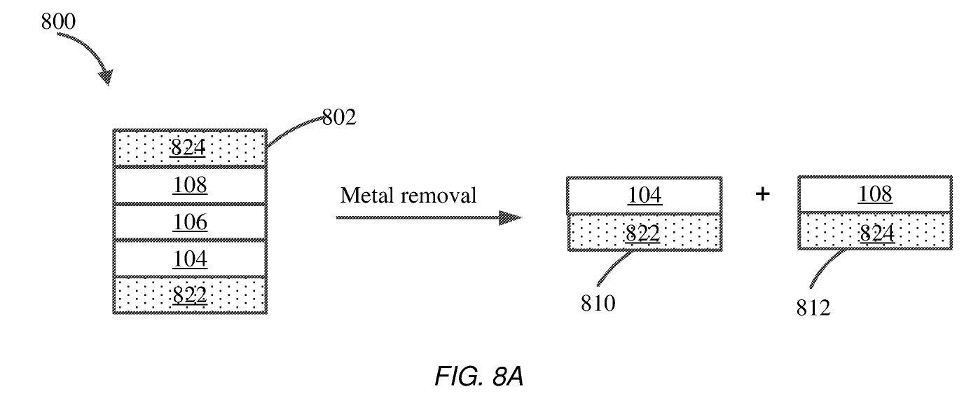

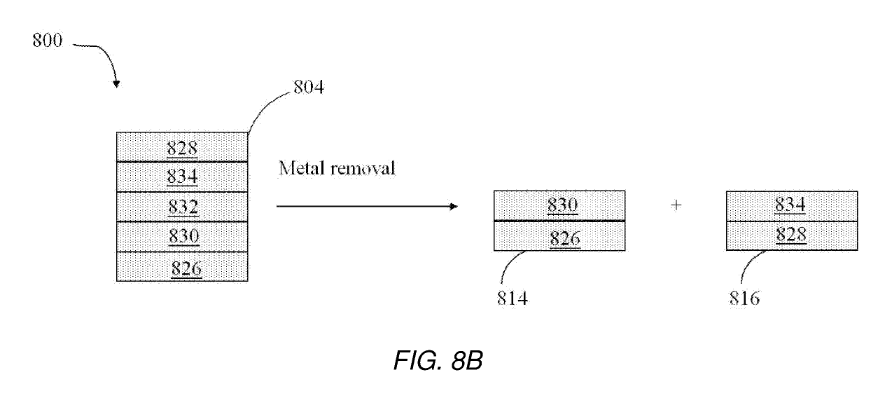

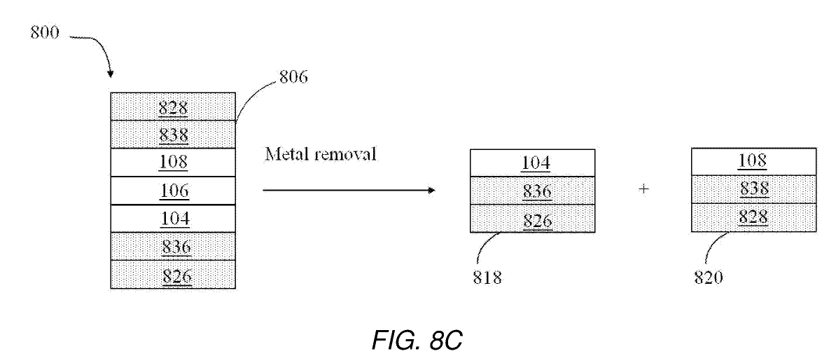

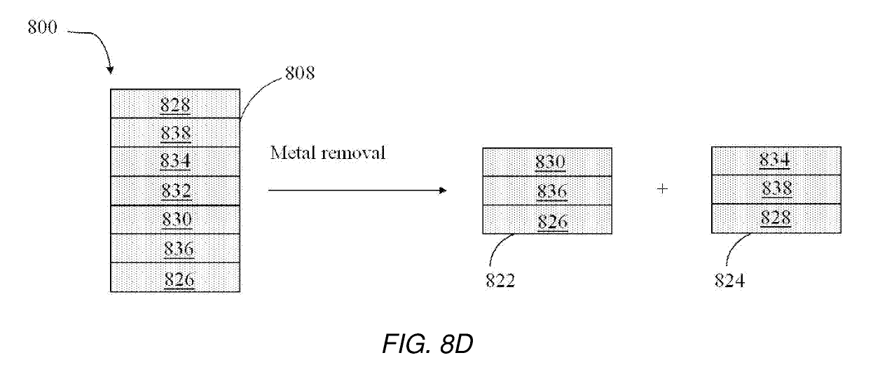

FIGS. 8A-8D are schematics of embodiments of making graphene electrodes from the perforated substrates and/or perforated graphene layers. The method 800 can include obtaining a layered stack 802, layered stack 804, layered stack 806 and/or layered stack 808 and subjecting the stacks to a process that removes the metal layer 106 or the perforated metal layer 832 from the layered stacks to produce two graphene electrodes 810 and 812 shown in FIG. 8A, the two graphene electrodes 814 and 816 shown in FIG. 8B, the two graphene electrodes 818 and 820 shown in FIG. 8C or the two graphene electrodes 822 and 824 shown in FIG. 8D. As shown in FIG. 8A, layered stack includes the perforated substrates 826 and 828, the graphene layers 104 and 108, and the metal layer 106. The perforations can be holes or openings in the substrate and may extend partially or completely through the substrate. A portion or substantially all of the substrates can be perforated. In some embodiments, only one substrate is perforated. For example, stack 802 can include the perforated first stack 826, the graphene layer 104, the metal layer 106, the second graphene layer 108, and the second substrate 110. As shown in FIG. 8B, stack 804 includes the perforated substrates 826 and 828, the perforated graphene layers 830 and 834, and the perforated metal layer 832 between the two perforated graphene layers. The graphene electrodes 814 and 816 include the perforated substrates 826 and 828 attached to the graphene layers 830 and 834, respectively. The stack 806 (shown in FIG. 8C) includes the perforated first substrate 826, the perforated first adhesive layer 836, the first graphene layer 104, the metal layer 106, the second graphene layer 108, the perforated adhesive layer 838, and the perforated second substrate layer 828. After the metal removal, the graphene electrodes obtained 818 and 820 include the perforated substrate 826 and 828, the perforated adhesive layer, 836 and 838, and the graphene layers 104 and 108, respectively. The stack as shown in FIG. 8D includes the perforated first substrate 826, the perforated first adhesive layer 836, the perforated first graphene layer 830, the perforated metal layer 832, the perforated second graphene layer 834, the perforated adhesive layer 838 and the perforated second substrate layer 828. After the metal removal, the graphene electrodes obtained 822 and 824 include the perforated substrate 826 and 828, the perforated adhesive layer 836 and 838, and the perforated graphene layer 830 and 834, respectively. The possible techniques to remove the metal are, for example, the etching in the solution 210, electrochemical etching, mechanical delamination, or known/sq. metal removal processes. The electrodes 810, 812, 814, 816, 818, 820, 822, and 824 can be transparent and are conductive (for example, each electrode can have a sheet resistance of 1.5 to 2 kΩ/sq.).

### H. Patterned or Functionalized Graphene Layers

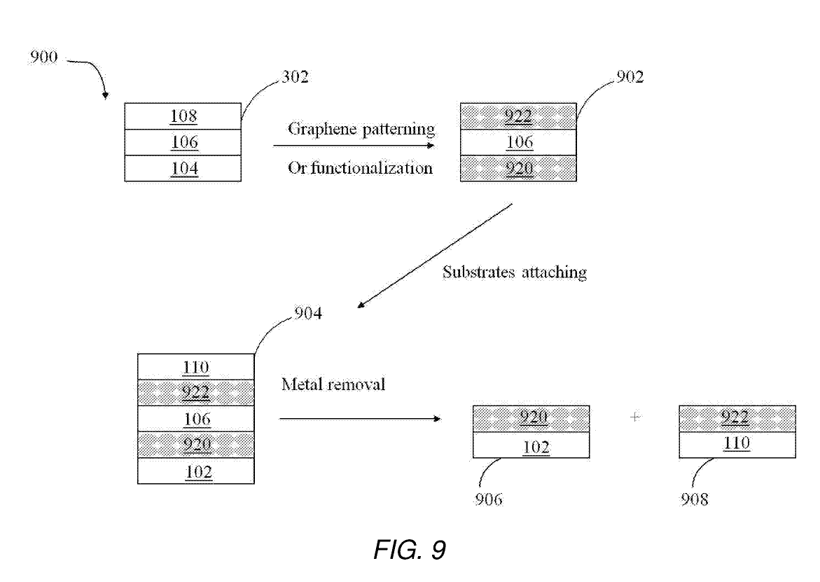

As shown in FIG. 9, the graphene layers 104 and 108 of stack 302 can be patterned or functionalized to produce the stack 902. The stack 902 includes the first patterned or functionalized graphene layer 920, the metal layer 106 and the second patterned or functionalized graphene layer 922. The patterning can be, for example, plasma or other treatments where some parts of graphene are removed. The functionalization can be with nanoparticles, or a substitutional doping, or a covalent or a non-covalent functionalization, as described throughout this Specification. The substrate layers 102 and 110 can be attached or adhered to the first and the second patterned or functionalized graphene layers 920 and 922 to form stack 904. Stack 904 is subjected to a metal removal process to produce two patterned or functionalized graphene electrodes 910 and 912. Graphene electrodes 906 and 908 include the substrate layers 102 and 110, and the patterned graphene layers 920 and 922, respectively. In some embodiments, only one of the graphene stacks is patterned or functionalized. For example, stack 904 can include the first substrate 102, the patterned/functionalized graphene layer 922, the metal layer 106, the graphene layer 108, and the second substrate 110. The electrodes 906 and 908 can be transparent and are conductive (for example, each electrode can have a sheet resistance of 1.5 to 2 kΩ per square).

### I. Materials Used

While the present invention has used graphene in the description of the conductive material, it should be understood that this present invention applies to other conductive material or active material. By way of example only, one such active material that can be used in the transfer processes of the present invention includes boron nitride (e.g., CVD produced boron nitride, where a metal layer includes on each opposing side first and second boron nitride layers). Other non-limiting examples include 2D materials grown or deposited on metals, like: MoS₂, NbSe₂, WS₂, NiS₂, MoSe₂, WSe₂, VSe₂, TiS₂. Finally the present invention contemplates 2D materials functionalized by chemical or physical treatments, for example, the functionalization by covalent bonding (the addition of free radicals to sp₂ carbon atoms of graphene, or addition of dienophiles to carbon-carbon bonds, or addition of chromophores, or addition of other organic molecules, or linkage to polymers, or attachments of hydrogen and halogens toward graphene derivatives like graphane or fluorographene); the functionalization by non-covalent bonding of graphenes; the functionalization with nanoparticles (precious metal nanoparticles, metal oxide nanoparticles, quantum dots, etc.), and dopants. Furthermore, each one of these active or conductive materials can be deposited on the metal layer in different ways, for example by chemical vapor deposition, plasma enhanced chemical vapor deposition (PECVD), segregation or by other methods.

The substrate layer used in the present invention can be any flexible material compatible with an adhesive material used in the present invention and suitable for laminating, hot or cold roll-to-roll-processing, extruding, or heating and pressuring processing. Flexible materials include plastics. Non-limiting examples of plastics include thermoplastics and thermosetting polymers. Non-limiting examples of substrates that can be used in the present invention include polyolefins such as polyethylene, polypropylene, polybutene, polyisobutylene and copolymers thereof, polyethylene terephthalate (PET), a polycarbonate (PC) family of polymers, polybutylene terephthalate (PBT), poly(1,4-cyclohexylidene cyclohexane-1,4-dicarboxylate) (PCCD), glycol modified polycyclohexyl terephthalate (PCTG), poly(phenylene oxide) (PPO), polypropylene (PP), polyethylene (PE), polyvinyl chloride (PVC), polystyrene (PS), polyethyleneimine (PEI) and its derivatives, thermoplastic elastomer (TPE), terephthalic acid (TPA) elastomers, poly(cyclohexanedimethylene terephthalate) (PCT), polyethylene naphthalate (PEN), polyamide (PA), polystyrene sulfonate (PSS), or polyether ether ketone (PEEK) or combinations or blends thereof. The polymers used in the substrate layer have a glass transition temperature between −5 and 430° C. and/or a Vicat softening temperature between 50 and 200° C. A person having ordinary skill in the art would be able to readily chose polymers having these temperatures by referring to reference manuals or by performing well-known assays (e.g., Vicat softening point is a standardized test that is used to determine the temperature at which a material is penetrated to a depth of 1 mm by a flat-ended needle with a 1 mm² circular or square cross-section—for the Vicat A test, a load of 10 N is used; for the Vicat B test, the load is 50 N.). By way of example, the glass transition temperature (Tg) of PET is approximately 70° C., while its Vicat B softening temperature is approximately 82° C., and its melting point is about 260° C. Table 1 below provides non-limiting substrates (and the respective glass transition and Vicat softening temperatures) that can be used in the context of the present invention.

TABLE 1

| | Glass | | |
|---|---|---|---|
| | transition | Melting | Vicat B |
| | temperature | point | at load of |
| Polymer Name | (Tg) ° C. | (Tm) ° C. | 50 N ° C. |
| Polyethylene terephthalate (PET) | 70 | 260 | 82 |
| Polycarbonate (PC) | 147 | 155 | 145 |
| Polybutylene terephthalate (PBT) | 68 | 223 | 120 |
| Poly(1,4-cyclohexylidene cyclohexane- | 70 | 225 | 120 |
| 1,4-dicarboxylate) (PCCD) | | | |
| Poly(phenylene oxide) (PPO) | 215 | 262 | 120 |
| Polypropylene (PP) | −20 | 170 | 108 |
| High density polyethylene (HDPE) | −90 | 130 | 128 |
| Polyvinyl chloride (PVC) | 100 | 170 | 80 |
| Polystyrene (PS) | 100 | 240 | 161 |
| Polymethylmethacrylate (PMMA) | 110 | 160 | 145 |
| Polyethyleneimine (PEI) | 215 | 380 | 125 |
| Terephthalic acid (TPA) elastomers | 425 | 500 | — |
| Glycol modified polycyclohexyl | −3 | 207 | 170 |
| terephthalate (PCTG) | | | |
| Thermoplastic elastomer (TPE) | 75 | 235 | 90 |
| poly(cyclohexanedimethylene | 90 | 274 | 110 |
| terephthalate) (PCT) | | | |

The adhesive layers used in the present invention can be thermally activated adhesives, pressure activated adhesives, solvent activated adhesives, UV-activated adhesives, high-voltage electric discharge activated adhesives, or plasma activated adhesives. In a preferred aspect of the invention, the adhesive layer is a thermally activated adhesive. The thermally activated adhesive has a melt index from about 2 to 200 g/10 min. The thermally activated or solvent activated adhesives can be elastomers, thermoset, thermoplastics or any combination thereof. Examples of thermally activated adhesives include elastomers, thermosets, thermoplastics that melt without decomposition when heated, polyethylene acrylate polymer or copolymer thereof, ethylene vinyl acetate copolymer (EVA), ethylene methyl acrylate copolymers (EMA), ethylene acrylic acrylate (EAA), ethylene ethyl acrylate (EEA), or ethylene methyl acidic acrylate (EMAA), or any combination thereof. A solvent activated adhesive is a dry adhesive film that is rendered tacky, just prior to use, by application of a solvent or moisture. Non-limiting examples of solvents include toluene, methyl ethyl ketone, cyclohexanone, and trichloroethylene. Examples of solvent activated adhesives include thermoplastic polyurethanes, phenolic resins, crepe rubber, or any combination thereof. Pressure activated adhesives can include any polymer or polymer blend that flows upon application of pressure at room temperature. When the pressure is removed, the viscosity of the polymer is high enough to adhere to the surface of the substrate layer and the graphene layer. Pressure activated adhesives can be used in cold roll-to-roll processes. Pressure activated adhesives can be a blend of polymers and resins. Non-limiting examples of polymers used in pressure active adhesives include natural rubber, vinyl ethers, acrylic-based polymers, butyl rubber-based polymers, styrene block copolymers, silicon polymers and nitrile-based polymers. UV-activated adhesives are activated upon application of a ultra-violet light at a chosen wavelength, for example, 300 nm. Non-limiting examples, of UV-activated adhesives include thermoplastic elastomers or resins such as styrene-based thermoplastic elastomers, styrene-based elastomers of polybutadiene unit or polyisoprene unit, styrene-butadiene-styrene block copolymer (SBS), styrene-isoprene-styrene block copolymer (SIS), styrene-(ethylene-butylene)-styrene block copolymer (SEBS), styrene-(ethylene-propylene)-styrene block copolymer (SEPS), epoxy-modified by glycidyl methacrylate, polystyrene resins, phenoxy resins and or any combination thereof.

### EXAMPLES

The present invention will be described in greater detail by way of specific examples. The following examples are offered for illustrative purposes only, and are not intended to limit the invention in any manner. Those of skill in the art will readily recognize a variety of noncritical parameters which can be changed or modified to yield essentially the same results.

### Example 1

### Process to Produce a Single Graphene Laminate

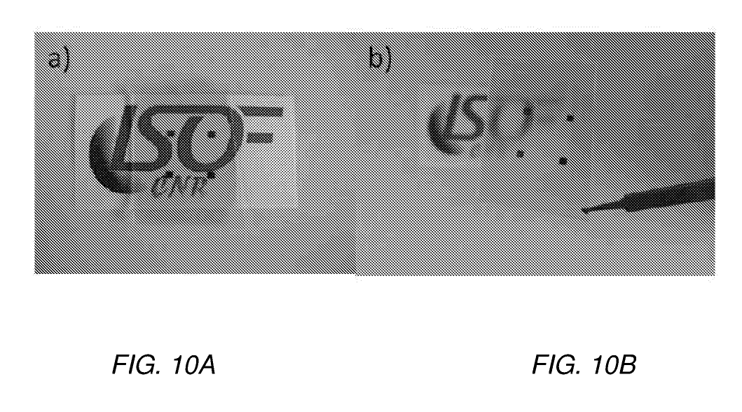

A layer of paper was inserted in a polyethylene terephthalate (PET) pouch (thickness 75 μm) with the inside surfaces of the pouch coated with heat-activated adhesive. Above the paper, a CVD graphene on copper was placed, and then the pouch was closed. The pouch was passed through a hot commercial laminator. After removal from the laminator the pouch was cooled to room temperature and cut at the borders to obtain two stacks. The first stack included PET, adhesive, graphene and copper. The second stack includes PET, adhesive and paper. The first stack was suspended in an aqueous etching solution of ferric chloride until all the copper was removed. The resulting graphene laminate (PET layer, adhesive layer, graphene layer) was washed with water. The graphene laminate was cut into samples having a dimension of 1×1 cm² and 2×2 cm². The sheet resistance of the samples was 1.5-2 kΩ/sq as measured with a 4-probe Van der Paw system (distance of the probes: 1 cm). The layer demonstrated homogeneous resistance in every direction, thus the graphene was determined to be completely transferred on to the PET. The graphene laminates were transparent. The sheets had a haze value of about 91% at 635 nm, measured with Agilent Universal Spectrophotometer, Cary 7000 with an angle resolution of 2°. FIGS. 10A and 10B are images of a printed material as viewed through the graphene laminates. FIG. 10A is a view of the image of the printed material when the graphene laminate is close to the material. FIG. 10B is a view of the image of the printed material when the graphene laminate is at a distance of 20 cm from the material. The black squares on the graphene laminate are gold dots that have been deposited on the laminate by evaporation. The graphene laminate produced by directly transferring the graphene to a polymeric substrate using the methods of the present invention is transparent and has sufficient conductivity to be used an electrode or interconnect in electronic devices.

### Example 2

### Process to Produce Two Graphene Laminates

A CVD graphene on copper was inserted in a polyethylene terephthalate (PET) pouch (thickness 125 μm) with the inside surfaces of the pouch coated with heat-activated adhesive and then the pouch was closed. The pouch was passed through a hot commercial laminator. After removal from the laminator the pouch was cooled to room temperature and cut at the borders to obtain one stack. The stack included PET, adhesive, graphene, copper, graphene, adhesive, PET. The stack was immersed in an aqueous etching solution of ferric chloride or an aqueous etching solution of hydrochloric acid and hydrogen peroxide until all the copper was removed. The resulting two graphene laminates, each one composed of: a PET layer, adhesive layer, graphene layer, were separated and washed with water. The graphene laminates were cut into samples having a dimension of 1×1 cm² and 2×2 cm². The sheet resistance of the samples were 500 Ω/sq-2 kΩ/sq as measured with a 4-probe Van der Paw system (distance of the probes: 1 cm). The layers demonstrated homogeneous resistance in every direction, thus the graphene was determined to be completely transferred on to the PET. The graphene laminates were transparent. The sheets had a haze value of about 50% at 635 nm, measured with Agilent Universal Spectrophotometer, Cary 7000 with an angle resolution of 2°.

### Example 3

### Process to Produce Two Graphene Laminates

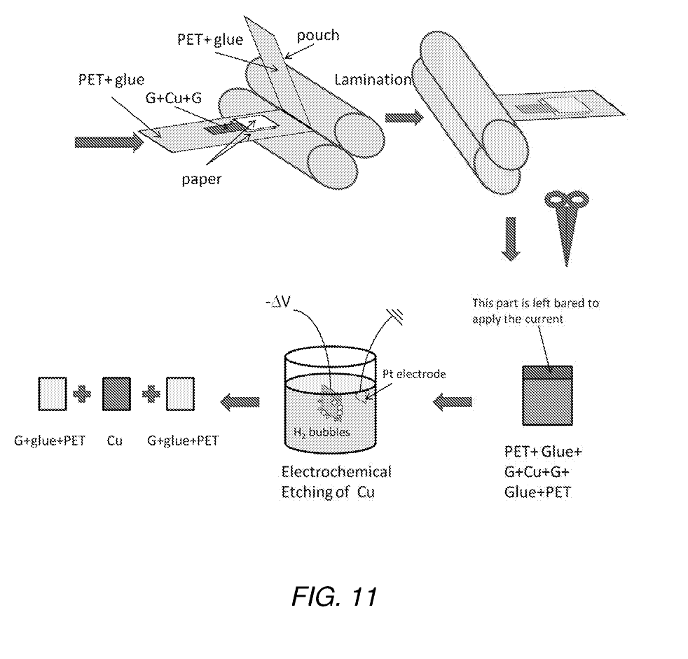

As shown in FIG. 11, a CVD graphene on copper foil positioned between two pieces of paper was inserted in a polyethylene terephthalate (PET) pouch (thickness 75 μm) with the inside surfaces of the pouch coated with heat-activated adhesive. The pieces of paper covered only a small portion of the sample (about 5 mm), and was not adhered to the surface of the pouch. The pouch was closed, and the pouch was passed through a hot commercial laminator. After removal from the laminator the pouch was cooled to room temperature and the borders were cut and the paper was removed to obtain one stack. The stack included PET, adhesive, graphene, copper, graphene, adhesive, PET. The portion of the CVD graphene that was covered by the paper was not attached to the PET and was used to secure an electrode. The stack was immersed in an aqueous etching solution of ammonium persulfate. A voltage of −5V was applied between the stack and a platinum electrode and an electrical current started to flow through the solution. The air bubbling, formed due to the reduction of water delaminates and partially etching of the copper, allowed for the complete detachment of the copper from the graphene layer. The resulting two graphene laminates, each one composed of: a PET layer, adhesive layer and a graphene layer, were separated and washed with water. The graphene laminates were cut into samples having a dimension of 1×1 cm² and 2×2 cm². The sheet resistance of the samples were 500 SΩ/sq-2 kΩ/sq as measured with a 4-probe Van der Paw system (distance of the probes: 1 cm). The layers demonstrated homogeneous resistance in every direction, thus the graphene was determined to be completely transferred on to the PET. The graphene laminates were transparent. The sheets had a haze value of about 50% at 635 nm, measured with Agilent Universal Spectrophotometer, Cary 7000 with an angle resolution of 2°.

### Example 4

### Process to Produce Two Multilayered Graphene Laminates

Multilayer CVD graphene on nickel foil was inserted in a polyethylene terephthalate (PET) pouch (thickness 75 μm) with the inside surfaces of the pouch coated with heat-activated adhesive and then the pouch was closed. The pouch was passed through a hot commercial laminator. After removal from the laminator the pouch was cooled to room temperature and cut at the borders to obtain one stack. The stack included PET, adhesive, multilayer graphene, nickel, multilayer graphene, adhesive, PET. The stack was immersed in an aqueous etching solution of hydrochloric acid and hydrogen peroxide until all the nickel was removed. The resulting two multilayer graphene laminates, each one composed by: a PET layer, adhesive layer, multilayer graphene, were separated and washed with water. The multilayer graphene laminates were cut into samples having a dimension of 1×1 cm² and 2×2 cm². The sheet resistance of the samples were 6 Ω/sq-10 Ω/sq as measured with a 4-probe Van der Paw system (distance of the probes: 1 cm). The layers demonstrated homogeneous resistance in every direction, thus the graphene was determined to be completely transferred on to the PET. The graphene laminates have a transmittance value of 5% at 600 nm measured by Avantes Spectrometer.

1.-26. (canceled)

27. A method of making an active material, the method comprising,
(a) obtaining a layered stack comprising a first substrate layer, a first 2-dimensional material layer attached to the first substrate layer, a metal layer attached to the first 2-dimensional layer, a second 2-dimensional layer attached to the metal layer, and a second substrate layer attached to second 2-dimensional layer, wherein the first and second 2-dimensional active material layer is selected from graphene, h-BN, MoS₂, NbSe₂, WS₂, NiS₂, MoSe₂, WSe₂, VSe₂, TiS₂, or any combination thereof grown onto each opposing sides of the metal layer, and wherein the whole layered stack is perforated
(b) removing the metal layer from the layered stack by a chemical process or an electrochemical process; and
(c) obtaining two conductive or active materials,
wherein the first conductive or active material comprises the first substrate layer attached to the first 2-dimensional layer,
wherein the second conductive or active material comprises the second substrate layer attached to the second 2-dimensional layer, and
wherein the first and second 2-dimensional material layers are conductive or active layers.

28-30. (canceled)

31. The method of claim 27, wherein the first and second substrate layers are polymeric layers and the metal layer is a copper layer or a nickel layer.

32. The method of claim 27, wherein the first and the second 2-dimensional material layers are patterned or functionalized.

33. The method of claim 27, wherein step (b) is the chemical process and the chemical process comprises etching the metal layer with an aqueous solution comprising iron chloride, ammonium persulfate, or nitric acid.

34. The method of claim 27, wherein step (b) is the electrochemical process, and the electrochemical process comprises applying direct current to the metal layer.

35. The method of claim 27, wherein one or both the substrate layers and the 2-dimensional material layers are attached together through adhesive layers positioned between the substrate layer and the 2-dimensional material layer, wherein the adhesive layers are perforated and wherein the adhesive layers are selected among thermally activated adhesive, pressure activated adhesive, a solvent activated adhesive, a UV activated adhesive, a plasma active adhesive, or any combination thereof.

36. The method of claim 27, wherein one of both of the substrate layers and one or both of the 2-dimensional material layers are attached together by heat, pressure, plasma activation, electrostatic interaction, or any combination thereof.

37. The method of claim 27, wherein the 2-dimensional material layers and the metal layer are not perforated.

38. The method of claim 37, wherein one or both the substrate layers and the 2-dimensional material layers are attached together through adhesive layers positioned between the substrate layer and the 2-dimensional material layer, wherein the adhesive layers are perforated and wherein the adhesive layers are selected among thermally activated adhesive, pressure activated adhesive, a solvent activated adhesive, a UV activated adhesive, a plasma active adhesive, or any combination thereof.

39. The method of claim 37, wherein one of both of the substrate layers and one or both of the 2-dimensional material layers are attached together by heat, pressure, plasma activation, electrostatic interaction, or any combination thereof.

40. A conductive or active material comprising a perforated 2-dimensional material layer attached on a perforated polymeric substrate layer, wherein the 2-dimensional material layer is selected from graphene, h-BN, MoS₂, NbSe₂, WS₂, NiS₂, MoSe₂, WSe₂, VSe₂, TiS₂ or any combination thereof, wherein the conductive or active layer is used as a sensor, or a capacitor, or a battery, a catalyst, or an optoelectronic device.

41. The conductive or active material of claim 41, wherein the 2-dimensional material layer is patterned or functionalized.

42. The conductive or active material of claim 41, wherein the substrate layer and the 2-dimensional material layer are attached together through an adhesive layer positioned between the substrate layer and the 2-dimensional material layer, wherein the adhesive layer is perforated and wherein the adhesive layer is selected among thermally activated adhesive, pressure activated adhesive, a solvent activated adhesive, a UV activated adhesive, a plasma active adhesive, or any combination thereof.

43. The conductive or active material of claim 41, wherein the substrate layer and the second 2-dimensional material layer are attached together by heat, pressure, plasma activation, electrostatic interaction, or any combination thereof.

44. A layered stack comprising a first substrate attached to a first 2-dimensional material layer opposite to the first substrate, attached to a metal layer opposite to the first substrate, a second 2-dimensional material layer attached to the metal layer opposite to the first 2-dimensional material layer and a second substrate layer attached to the second 2-dimensional material layer opposite to the metal layer, wherein the 2-dimensional material layer is selected among graphene, h-BN, MoS₂, NbSe₂, WS₂, NiS₂, MoSe₂, WSe₂, VSe₂, TiS₂ grown onto each opposing sides of the metal layer, and wherein the whole layered stack is perforated.

45. The layered stack of claim 44, wherein the first and second substrate layers are polymeric layers and the metal layer is a copper layer or a nickel layer.

46. The layered stack of claim 44, wherein the first and the second 2-dimensional material layers are patterned or functionalized.

47. The layered stack of claim 44, wherein the 2-dimensional material layers and the metal layer are not perforated.

48. The layered stack of claim 44, wherein one or both the substrate layers and the 2-dimensional material layers are attached together through adhesive layers positioned between the substrate layer and the 2-dimensional material layer, wherein the adhesive layers are perforated and wherein the adhesive layers are selected among thermally activated adhesive, pressure activated adhesive, a solvent activated adhesive, a UV activated adhesive, a plasma active adhesive, or any combination thereof.

49. The layered stack of claim 44 wherein one or both of the substrate layers and one or both of the 2-dimensional material layers are attached together by heat, pressure, plasma activation, electrostatic interaction, or any combination thereof.
